(19) United States
(12) Patent Application Publication
(10) Pub. No.: US 2024/0330545 A1
(43) Pub. Date: Oct. 3, 2024

(54) SYSTEM AND METHOD FOR TRAINING MOBILE ROBOTS IN VIRTUAL ENVIRONMENT

(71) Applicants: Andres Felipe Chavez Cortes, El Cerrito, CA (US); David Eduardo Rodríguez Acevedo, Miami, FL (US); Sergio Eduardo Pachón Reyes, Medellín (CO); Andres Felipe Rengifo Sanchez, Medellín (CO)

(72) Inventors: Andres Felipe Chavez Cortes, El Cerrito, CA (US); David Eduardo Rodríguez Acevedo, Miami, FL (US); Sergio Eduardo Pachón Reyes, Medellín (CO); Andres Felipe Rengifo Sanchez, Medellín (CO)

(21) Appl. No.: 18/620,282

(22) Filed: Mar. 28, 2024

Related U.S. Application Data
(60) Provisional application No. 63/492,959, filed on Mar. 29, 2023.

(51) Int. Cl. G06F 30/27

(52) U.S. Cl. CPC G06F 30/27

(57) ABSTRACT

A method for training mobile robots in virtual environment involves operating a virtual environment generation system configured to render a virtual environment comprising a course and obstacles. The method operates as a virtual robot in the virtual environment and a training interface with a training layer to adjust the complexity of the course and types and quantity of the obstacles. The method determines a navigation score for the virtual robot. The method logs frames from the sensor channels of the virtual robot while navigating through the course and the obstacles and communicates logged frames to a machine learning pipeline that applies at least one filter to the logged frames to generate training frames for a machine learning model. The method retrains the machine learning model with the training frames to generate a model update and applies the model update to the classification model and generates a new virtual robot version.

### CROSS-REFERENCE TO RELATED APPLICATIONS

This application claims the benefit of U.S. provisional application No. 63/492,959 filed Mar. 29, 2023.

### BACKGROUND

Transport of articles including food and medicine to a specific location, or multiple places, have posed a problem since years now, and the idea of robots performing these tasks is still sounds like a futuristic idea to many members of the general public after these many years of robot evolution.

Nowadays, thanks to technological improvements, robotic last mile deliveries have become a reality, and introducing autonomous driving to it is going to transform it forever. With this intention, this virtual environment is built with the purpose of training autonomous delivery vehicles in a simulated environment.

Autonomous and semi-autonomous mobile robots are a growing field of innovation. An autonomous robot relates to a self-driving vehicle that is capable of operation without human input. Urban areas introduce numerous challenges for autonomous robots as they are rather unstructured and dynamic. With the scope of adding autonomy to the robots and using them for delivery operation, a Virtual Training Environment simulator is designed to train the robot intelligence model. This Virtual Training Environment provides learning and navigation systems for mobile robots designed to operate in crowded city environments and pedestrian zones.

Robots that can successfully navigate in urban environments and pedestrian zones have to cope with a series of challenges including complex three-dimensional settings and highly dynamic scenes paired with unreliable GPS information. So in order to refrain any marginal error, which may lead to some unintentional accidents, this simulator is created, in which an operator can practice navigating vehicles in the unstructured environment with pre-defined goals, and a machine learning system has been developed which learns from every run instance by an operator to make autonomous navigation better.

Virtual environments may be used to train autonomous vehicles. However, such environments have historically been limited in their complexity and, thus, in their ability to provide adequate training data for particularly complicated environments.

### BRIEF SUMMARY

A virtual training environment built around a 3D graphics platform, provides a simulation of a virtual training environment to train robots for autonomous navigation. This virtual training environment is designed with multiple camera angle viewpoints and focuses on mobile robot navigation on sidewalks. With mobile robots traversing on sidewalks, it becomes important to avoid any collision with the pedestrian, and so machine learning systems help robots avoid any collision.

The training utility of a virtual training environment is greatly expanded by automatically creating variations of the experiences generated while navigating the virtual environment. Navigation of the environment results in views of the environment that are dependent on the navigation instructions and route. These views are represented by “frames” as would be mimicking images received from a camera system while navigating a real-world environment. For frames generated in the virtual training environment additional training frames are generated by automatically varying characteristics of the environment. These characteristics can include, but are not limited to, surface texture, surface colors, surface patterns, surface reflectivity, lighting intensity and source locations.

The training utility of a virtual training environment is adapted to train virtual vehicles in different training conditions to navigate from one point to another smoothly.

The automatically generated training frames are used to improve the training of a semiautonomous vehicle. Successful training has been achieved in very complicated environments such as city sidewalks. Machine learning systems are trained for self-navigation of ground level vehicles having multiple cameras and sensors.

The virtual training environment is made compatible with all major operating systems. It also has 3 different virtual camera systems integrated.

The virtual training environment is equipped with different mission modes with difficulty levels ranging from Easy to Intermediate, to provide a realistic experience of driving a robot/vehicle in all possible environment conditions.

The virtual training environment also has a scoring system, which calculates score based upon parameters like task completion and crashes, providing feedback of the test run and thereby helping improve operator performance which in turn will lead to a better training of machine learning systems.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates an aspect of the subject matter in accordance with one embodiment.

FIG. 2 illustrates a routine 200 in accordance with one embodiment.

FIG. 3 illustrates a frame 300 generated during navigation of a virtual environment in accordance with one embodiment.

FIG. 4 illustrates top down view 400 of the virtual robot in the virtual environment in accordance with one embodiment.

FIG. 5 illustrates a frame 500 of the virtual robot in the virtual environment in accordance with one embodiment.

FIG. 6 illustrates a training frame 600 with a filter applied in accordance with one embodiment.

FIG. 7 illustrates a training frame 700 in accordance with one embodiment.

FIG. 8 illustrates a driver interface in accordance with one embodiment.

FIG. 9 illustrates a user interface 900 in accordance with one embodiment.

FIG. 10 illustrates a user interface 1000 in accordance with one embodiment.

FIG. 11 illustrates a user interface 1100 in accordance with one embodiment.

FIG. 12 illustrates a user interface 1200 in accordance with one embodiment.

FIG. 13 illustrates a comparison between image classification, object detection, and instance segmentation.

FIG. 14 illustrates a Region-based Convolution Network 1400.

FIG. 15 illustrates a Fast Region-based Convolutional Network 1500.

FIG. 16 illustrates a Faster Region-based Convolutional Network 1600.

FIG. 17 illustrates a comparison of segmentation accuracy (mIoU) and inference speed (FPS) on the Cityscapes test set.

FIG. 18 illustrates an architecture overview of a semantic learning model.

FIG. 19 illustrates a conventional encoder-decoder in which the decoder keeps the features channels the same and an encoder and proposed Flexible and Lightweight Decoder (FLD).

FIG. 20A illustrates a framework of a Unified Attention Fusion Module (UAFM).

FIG. 20B illustrates a framework of a Spatial Attention Module.

FIG. 20C illustrates a framework of a Channel Attention Module.

FIG. 21 illustrates a Simple Pyramid Pooling Module (SPPM).

FIG. 22 illustrates a qualitative comparison on the Cityscapes validation set.

FIG. 23 illustrates a simplified system 2300 in which a server 2304 and a client device 2306 are communicatively coupled via a network 2302.

FIG. 24 is an example block diagram of a computing device 2400 that may incorporate embodiments of the present invention.

FIG. 25 illustrates a system 2500 in accordance with one embodiment.

### DETAILED DESCRIPTION

A method for training Mobile Robots in virtual environment involves operating a virtual environment generation system configured to render a virtual environment comprising a course and obstacles. The method configures a robotic operating system comprising a navigation controller, a classification model, and sensor channels to operate as a virtual robot in the virtual environment. The method operates a training interface configured to observe, configure, and record interactions between the virtual robot and the virtual environment, wherein the training interface comprises a user interface dashboard, a testing layer, a frame logger, and a scoring system. The method operates the training layer to adjust the complexity of the course and types and quantity of the obstacles presented to the virtual robot in the virtual environment configured by the testing configurations from the user interface dashboard. The method operates the movement of the virtual robot in the virtual environment by way of a navigation controller to traverse through the course. The method logs frames from the sensor channels of the virtual robot while navigating through the course and the obstacles through operation of the frame logger. The method determines a navigation score for the virtual robot on interactions on the course through operation of the scoring system. The method communicates logged frames to a machine learning pipeline and applies at least one filter to the logged frames to generate training frames for a machine learning model. The method retrains the machine learning model with the training frames to generate a model update for the classification model. The method applies the model update to the classification model and generates a new virtual robot version. The method ranks different virtual robot versions based on the navigation score.

In an embodiment, the sensor channels are image feeds of the virtual environment captured by virtualized cameras of the virtual robot. In an embodiment, the frame logger captures an array of images from the sensor channels.

In an embodiment, the at least one filter is utilized to simulate variations in image quality, lens interferences, light intensity, light source location, surface texture, surface color, surface pattern, and surface reflectivity.

In an embodiment, the machine learning model is a convolutional neural network for object classification.

In an embodiment, the frame logger is controlled by inputs from the user interface dashboard.

In an embodiment, the navigation controller is configured by navigation instructions.

In an embodiment, a computing apparatus comprises a processor and memory storing instructions that, when executed by the processor, configure the apparatus to operate a virtual environment generation system configured to render a virtual environment comprising a course and obstacles. The computing apparatus configures a robotic operating system comprising a navigation controller, a classification model, and sensor channels to operate as a virtual robot version in the virtual environment. The computing apparatus operates a training interface configured to observe, configure, and record interactions between the virtual robot and the virtual environment, wherein the training interface comprises a user interface dashboard, a testing layer, a frame logger, and a scoring system. The computing apparatus operates the testing layer to adjust the complexity of the course and types and quantity of the obstacles presented to the virtual robot in the virtual environment configured by the testing configurations from the user interface dashboard. The computing apparatus operates the movement of the virtual robot in the virtual environment by way of a navigation controller to traverse through the course. The computing apparatus logs frames from the sensor channels of the virtual robot while navigating through the course and the obstacles through operation of the frame logger. The computing apparatus determines a navigation score for the virtual robot on interactions on the course through operation of the scoring system. The computing apparatus communicates logged frames to a machine learning pipeline and applies at least one filter to the logged frames to generate training frames for a machine learning model. The computing apparatus retrains the machine learning model with the training frames to generate a model update for the classification model. The computing apparatus applies the model update to the classification model and generate a new virtual robot version. The computing apparatus ranks different virtual robot versions based on the navigation score.

In an embodiment, the sensor channels are image feeds of the virtual environment captured by virtualized cameras of the virtual robot. The frame logger captures an array of images from the sensor channels.

In an embodiment, the at least one filter is utilized to simulate variations in image quality, lens interferences, light intensity, light source location, surface texture, surface color, surface pattern, and surface reflectivity.

In an embodiment, the machine learning model is a convolutional neural network for object classification.

In an embodiment, the frame logger is controlled by inputs from the user interface dashboard.

In an embodiment, the navigation controller is configured by navigation instructions.

In an embodiment, a non-transitory computer-readable storage medium, the computer-readable storage medium including instructions that when executed by a computer, cause the computer to operate a virtual environment generation system configured to render a virtual environment comprising a course and obstacles. The computer-readable storage medium includes instructions that configure a robotic operating system comprising a navigation controller, a classification model, and sensor channels to operate as a virtual robot version in the virtual environment. The computer-readable storage medium includes instructions that operate a training interface configured to observe, configure, and record interactions between the virtual robot and the virtual environment, wherein the training interface comprises a user interface dashboard, a testing layer, a frame logger, and a scoring system. The computer-readable storage medium includes instructions that operate the testing layer to adjust the complexity of the course and types and quantity of the obstacles presented to the virtual robot in the virtual environment configured by the testing configurations from the user interface dashboard. The computer-readable storage medium includes instructions that operate the movement of the virtual robot in the virtual environment by way of a navigation controller to traverse through the course. The computer-readable storage medium includes instructions that log frames from the sensor channels of the virtual robot while navigating through the course and the obstacles through operation of the frame logger. The computer-readable storage medium includes instructions that determine a navigation score for the virtual robot on interactions on the course through operation of the scoring system. The computer-readable storage medium includes instructions that communicate logged frames to a machine learning pipeline and apply at least one filter to the logged frames to generate training frames for a machine learning model. The computer-readable storage medium includes instructions that retrain the machine learning model with the training frames to generate a model update for the classification model. The computer-readable storage medium includes instructions that apply the model update to the classification model and generate a new virtual robot version. The computer-readable storage medium includes instructions that rank different virtual robot versions based on the navigation score.

In an embodiment, the sensor channels are image feeds of the virtual environment captured by virtualized cameras of the virtual robot. The frame logger captures an array of images from the sensor channels.

In an embodiment, the at least one filter is utilized to simulate variations in image quality, lens interferences, light intensity, light source location, surface texture, surface color, surface pattern, and surface reflectivity.

In an embodiment, the machine learning model is a convolutional neural network for object classification.

In an embodiment, the frame logger is controlled by inputs from the user interface dashboard.

In an embodiment, additional filters may be provided to better emulate sensor noise. The additional filter may simulate better noise (e.g., interference, digital snow, etc.) of the cameras to simulate the noise. To simulate these effects may involve a comprehensive data. These feature may be generated by training a machine learning model to reproduce the noise based on a large sample data set of the given input emulating the noise.

In an embodiment, the virtual environment generation system may simulation software that has been developed in produce light photo realism to develop for a better representation of the environment. These virtual environment generation systems may improve lighting in certain scenarios such as rail road crossing and traffic intersections.

In an embodiment, the virtual environment generation system may be a simulation software such as Gazebo, CoppeliaSim, or Unity for Robotic operating systems (ROS).

Gazebo is widely utilized in academic and research settings due to its realistic physics simulation and ROS compatibility, making it an excellent tool for testing robots in complex, dynamic environments. The accuracy in sensor and actuator emulation enables a seamless transition from simulation to real-world application. On the downside, Gazebo's simulation environment can be very demanding on system resources, and newcomers may find its interface and extensive features daunting, posing a significant hurdle for those without prior experience.

CoppeliaSim, known for its rich feature set and flexible simulation capabilities, allows users to simulate not just the robot but also the sensors and the surrounding environment with a high degree of fidelity. It supports various physics engines and provides a customizable API, which is advantageous for specific simulation needs. However, the complexity of its features can also be a disadvantage, as it requires a steep learning curve to master, and some parts of its software being closed-source might not align with all users' preferences for open-source transparency and modifiability.

Unity, primarily a game development platform, offers unparalleled visual quality and the ability to create detailed environments, which can be beneficial for simulations requiring high levels of realism, such as those used in human-robot interaction studies. The integration with ROS through ROS # broadens its application to robotics. Nonetheless, its primary design as a game engine means that some robotics-specific features are not natively present and need to be implemented through additional scripting or plugins. Furthermore, for those without a background in game development or programming, Unity presents a significant learning curve.

In an embodiment, the machine learning model may be iteratively improved once a model meets minimum standards for operation. For instance if a model meets a performance baseline of accomplishing deliveries without crashes in standard conditions. The model may be iteratively improved upon through model updates and more complex training scenarios to improve upon the model.

A system and method for training mobile robots in a virtual environment comprises a 3D simulated environment with 2 tracks, one for training and other resembling city scenario. A virtual robot may be navigated between various navigation points. These points can be added in the virtual environment to operate the vehicle from one point to another based upon the navigation controller. These navigations points may be defined as part of a course.

A graphical user interface configured as driver interface may be provided as part of the training layer and displayed as an overlay on top of the sensor channel feed of the virtual environment. The graphical user interface may show information and statistics such as the virtual speed of the virtual robot as well as the direction the direction. The driver interface may also show the number of crashes that the virtual robot has had. The driver interface may be provided during remote operation of the virtual robot from a remote client. In some configurations, an operator is required to use a keyboard or a game controller to navigate the virtual robot from a remote location. The user controlled navigation of the virtual robot may be utilized to initially train the classification model utilized by the robotic operating system. Frames collected from the user controlled navigation may be utilized as a part of an initial training set for the machine learning model. In addition, navigation logic in the navigation controller may be improved to operate with the classification model.

For each run, a frame is logged at every moment, which is then parsed through frame logger to generate other training frames based upon different possible environment conditions. Based upon the dataset collected by mimicking different scenarios from the logged frames, the machine learning pipeline may run through the dataset for features and utilize the to train mobile robots for autonomous navigation.

The virtual environment has two different tracks, one for training (with easy and medium difficulty, with the former including dangerous curves) and a city scene. These are used to fetch training frames and test the autonomous routine. The city scene environment includes a sidewalk, which acts as the main pathway for delivery vehicles, bounded by a wall and a curb, these features may serve as basic obstacles for the virtual robot. There is also a transition between sidewalk and crosswalk, along with people walking/running to make it more realistic.

In an embodiment, navigation instructions are configured with the web server, which receives instructions from a remote client.

The frame logger is configured in a way that records on-board vehicle camera image along with meta frames. It also includes positioning co-ordinates of the vehicle in the world with the logged frame.

The machine learning pipeline can be configured to generate a plurality of frames (e.g., 2, 3, 5 or 10 or even more frames) from just one logged frame, giving an idea about same frame in different environment conditions by applying different filters. Different environment conditions include variation in image quality, lens interferences, light intensity, light source location, surface texture, surface color, surface pattern or surface reflectivity. It may be utilized to cover various changes in environment conditions due to change in one or multiple factors.

The driver interface may provide a clear view of the virtual environment from the robot's perspective. There is an option to change the view between pluralities of virtual camera positions. One of the views from the virtual camera originates from the viewpoint of a virtual vehicle seeing just the sidewalks.

The robotic operating system may have instructions configured as navigation logic in the navigation controller specifically configured for navigating on a sidewalk. These instruction may be set in such a way that if drift is noticed and the virtual robot begins to move onto the road, street, or area other than a sidewalk, the instructions may correct the virtual robot's path back towards the sidewalk.

In an embodiment, the navigation controller may be configured with navigation instructions from a server. However, the navigation logic within the navigation controller may also be configured to generate navigating instruction automatically.

The machine learning pipeline includes a machine learning model that may be convolutional neural network. The convolutional neural network may be trained using a method comprising of utilizing a training interface with a virtual environment to operate a virtual robot, that receives navigation instructions from a remote client and based upon those responses navigates a virtual robot in a virtual environment. Based upon the navigation instructions, a frame logger of the training interface logs the frames with a view of the virtual environment that are used to generate training frames of virtual environment. These frames further undergo a feature extraction, and a classifier is generated using machine learning model, which is used to train and retrain the classification model of the robotic operating system.

The navigation instructions, which are received by the virtual robot from a remote client, may be generated by a machine learning system

While the system described herein is used to train a machine learning model for vehicle navigation, the systems and methods disclosed may be applied to other training purposes, including for example, facial recognition, image tagging, object detection, obstacle avoidance, path planning, and decision making.

The virtual environment has different testing options may be configured through the training layer of the training interface. These different options include changing testing configurations which mimic the complexity of carrying operations in real world. It also gives an actual representation of different operation conditions based in different environments.

The virtual environment with the training layer may include courses with different difficulty levels ranging from easy to intermediate, thereby helping the operator to adjust to the virtual world slowly and help them perform better during their run. There may be different settings available in the virtual environment that can be adjusted by the testing configurations such as speed, number of people, lens distortion, etc., which can be changed anytime.

A scoring system may be provided as part of the training interface in the virtual environment. The scoring system may keep track of the performance by every logged-in operator, making it an interesting affair for both the operator and for the training system. This may additionally help determine the best human operated but as well may be utilized to determine the most efficient versions of the virtual robot.

During training, a course may include a few tasks involving food supply pick-up and delivery points, which changes every time based upon difficulty level. These tasks have multiple pickup points and delivery points both marked on the screen with different colored arrows to guide operator to reach them. A clock may keep track of and register the time in the system and pass this information to the scoring algorithm.

The Scoring system may use an algorithm to calculates the shortest distance between food supply and provided delivery point and uses it to compute distance travelled on auto pilot mode and manual driving model. Using these factors, a navigation score can be calculated. If the robot/virtual vehicle bumps into a building, walls, or a pedestrian in the simulator then a crash is reported in a crash meter on the driver interface. The more severe the crash, the more points will be deducted from the player's score from that particular point.

A Smart Decision-Making System (SDMS) may be established with a communication channels to send out commands to a virtual robot using a remote client. These commands may serve as communication settings that can be changed by an operator anytime to send images at a customizable size. These images may be sent on a hex string over a socket. The communication sends strings of hex values that need to be converted into a byte array object representing the image. This determines the image size segment. A server script may be written to perform this task automatically based upon the settings set by the operator. Furthermore, this communication channel may also used to send commands to the mobile robot, which are in the form of a range of integers, which controls steering and throttle parameters of a virtual vehicle.

The system and method for training mobile robots in a virtual environment may include a one touch frame logger. This frame logger may be configured to log specific frames for use in generating training frames with the push of one button. By pressing the button, an entire stream of frames from the virtual cameras are logged, and based upon configurations of the machine learning pipeline, new frames may be generated, which are then fed to the machine learning model. To retrain the model for improving the robotic operating system.

the system and method for training mobile robots provides learning and navigation systems for mobile robots designed to operate in crowded city environments and pedestrian zones. The system and method trains a virtual robot to adapt to sidewalks and streets. One objective behind developing this system and method is to train a model on which a mobile robot is able to move autonomously along the city without hitting pedestrians, running into any buildings, or crashing into walls. The virtual environment system comprises of a 3D simulated environment with 2 tracks, one for training and other resembling city scenario. Navigation points can be added in the environment to drive vehicle from one point to another based upon the navigation logic configured.

A graphical user interface as driver interface is provided along with a training layer on the virtual environment to show the speed of the virtual robot. An operator may be required to use a teleop keyboard operations or a game controller to control the virtual robot from a remote location using a remote client. The user controlled navigation of the virtual robot may then be utilized by a machine learning pipeline to generate multiple frames utilized for the training of a machine learning model.

The system and method may include logic as part of the machine learning pipeline for generating multiple frames out of a single logger frame. For each run of through a course by a virtual robot, a frame may be logged at every moment, which may then be parsed through the machine learning pipeline to generate additional training frames based upon different possible environment conditions by applying at least one filter. By generating additional datasets by applying filters to the logged frames, a machine learning pipeline is able to training the machine learning model on a plurality of conditions and scenarios.

The system and method has two different tracks, one for training (with easy and medium difficulty, with the former including dangerous curves) and a city scene. These are used to fetch training frames and test the autonomous routine. The city scene environment includes a sidewalk, which acts as the main pathway for delivery vehicles, bounded by a wall and a curb. There is also a transition between sidewalk and crosswalk, along with people walking/running to make it more realistic. These testing scenarios may be adjusted through testing configurations provided by the user interface dashboard. The navigation instructions may be configured through the web server, which receives instructions from a remote client.

The frame logger may be configured in a way that records on-board vehicle camera image along with metal frames. It also includes positioning co-ordinates of the vehicle in the world with the logged frame.

The machine learning pipeline may be configured to generate additional frames (e.g., 2, 3, 5 or 10 or even more frames) from just one logged frame, giving an idea about same frame in different environment conditions through the use of a filter. Different environment conditions include variation in image quality, lens interferences, light intensity, light source location, surface texture, surface color, surface pattern or surface reflectivity. So overall, it covers any type of change in environment conditions resulting due to change in one or multiple factors.

The machine learning model utilized by the system and method may include neural network implementation to train the classification model to identify environmental features.

The driver interface may provide a clear view of the virtual environment from the robot's perspective. The driver interface may be viewable through the remote client or through a the user interface dashboard. There is an option to change the view between pluralities of virtual camera positions. One of the views from the virtual camera system originates from the viewpoint of a virtual vehicle seeing just the sidewalks. The navigation logic may be configured such that it may redirect the path of the virtual robot back on to a sidewalk if a drift or collision is detected such that the virtual robot is moving towards obstacles such as a road or street or other path that is not on the side walk. Apart from configuring the navigation controller from the server, the navigation instructions may also be configured to generate the navigating instruction automatically.

The machine learning model may be trained using the virtual environment and the training interface with a robotic operating system that receives navigation instruction from a remote client, and based upon those responses navigates a virtual robot through a virtual environment. While the virtual robot is running based upon the navigation instructions, a frame logger logs the frames from the virtualized cameras in sensor channels from views of the virtual environment. These logged frames are then utilized by a machine learning pipeline to generate multiple frames of simulated environmental conditions utilizing filters. These training frames undergoes a feature extraction, and a classifier is generated utilizing neural networks, which is used to train a classification model in the robotic operating system.

The navigation instructions, which are received by the virtual robot from a remote client, may be generated by a machine learning system.

While the system described herein may be used to train a machine learning system for vehicle navigation, the systems and methods disclosed may be applied to other training purposes, including for example, facial recognition, image tagging, object detection, obstacle avoidance, path planning, and decision making.

The system and method has different mission modes to give an idea about the complexity of carrying operations in real world. It may also gives an actual representation of different operation conditions based in different environments. The system and method may be equipped with different difficulty levels ranging from easy to intermediate, thereby helping the operator to adjust to the virtual world slowly and help them perform better during their run.

There may also be different settings available in the virtual environment, through the training layer that may be utilized to adjust settings such as speed, number of people, lens distortion, etc., these settings may be changed at any time and may be part of testing configurations.

A scoring system may be added along with the training interface, and may keep track of the performance of individual operators as well as virtual robot versions. By adding a scoring system operators and version of the virtual robot operating different updates of the machine learning model may be ranked based on their performance. Every run or mission where the virtual robot navigates through a course may be supplied with a few tasks involving food supply pick-up and delivery points, which changes every time based upon difficulty level. These tasks have multiple pickup points and delivery points both marked on the screen with different colored arrows to guide operator to reach them. A clock may be added that keeps registering the elapsed time of the system and may be utilized as part of the calculation utilized by a scoring algorithm. The Scoring system may utilize the scoring algorithm which calculates the shortest distance between food supply and provided delivery point and uses it to compute distance travelled on auto pilot mode and manual driving model. Using these factors may be utilized to generate a navigation score. Additionally, If the robot/virtual vehicle bumps into a building, walls, or a pedestrian in the virtual environment, then a crash is reported in a crash meter on the driver interface. The more severe the crash, the more points may be deducted from the navigation score for that user or version from that particular point.

A Smart Decision-Making System (SDMS) communication channel may be established to send out commands to a mobile robot using a remote client. This communication settings can be changed by the operator anytime to send images at a customizable size. These images may be sent on a hex string over a socket. The communication may sends strings of hex values that may need to be converted into a byte array object representing the image. This determines the image size segment. A server script is written to perform this task automatically based upon the settings set by the operator. Furthermore, this communication channel may also be used to send commands to the mobile robot, which are in the form of a range of integers, which controls steering and throttle parameters of a virtual vehicle.

The system and method includes a one touch frame logger. With one push of a button, entire video frames from the virtual camera system may be logged, and based upon machine learning pipeline, new frames may be generated, which are then fed to the machine learning model. The machine learning model may then perform a feature extraction and train the vehicle model, which is used for navigating mobile robots autonomously.

The virtual environment system comprises a navigation controller configured for navigating a virtual robot within the virtual environment in response to navigation instructions; a navigation controller may be configured to receive the navigation instructions. A frame logger configured to log frames representative of views of the virtual environment, the views being from at least one point of view of the virtual robot. A machine learning pipeline maybe configured to automatically generate training frames based on the frames logged by the frame logger. The machine learning model may be trained or retrained with training frames to generate a model update. The training frames are utilized to train or retrain the machine learning model to navigate vehicles in real-world environments, to produce a trained machine learning system.

The virtual environment includes a sidewalk bounded by a wall and a curb. The virtual environment includes a transition between a sidewalk and a crosswalk and is configured to receive the navigation instructions from a remote client.

The frame logger is configured to log frames representative of at least 2, 3 or 4 views from the mobile robot and to log frames that include a view directly above the mobile robot.

The machine learning pipeline may be configured to generate at least 2, 3, 5 or 10 training frames based on one logged frame and to generate training frames through at least on filter simulating variations in image quality, lens interferences, light intensity, light source location, surface texture, surface color, surface pattern or surface reflectivity.

The machine learning model includes a neural network and other intelligent algorithms, to make learning a smart process for the virtual robot.

A driver interface is configured to present a view of the virtual environment to a human driver and is configured to change the view between a plurality of virtual camera positions. The view originates less than 10 inches above a sidewalk.

The navigation logic may be configured to automatically generate the navigating instructions.

A camera system may be configured to capture images within 20, 10, 5 degrees from a vertical axis centered on the vehicle. The virtual camera system can be configured in a way that is able to take images of the complete hemisphere. The virtualized cameras capture information through a sensor channel that captures views of the virtual environment.

In an embodiment, the machine learning model utilized as the basis for the classification model may be accomplished by a convolutional neural network that performs semantic segmentation. An example of a convolutional neural network that may be utilized in accordance with one embodiment is described below.

Semantic segmentation aims to precisely predict the label of each pixel in an image. It has been widely applied in real-world applications, e.g. medical imaging, autonomous driving, video conferencing, semiautomatic annotation. As a fundamental task in computer vision, semantic segmentation has attracted a lot of attention from researchers. With the remarkable progress of deep learning, a lot of semantic segmentation methods have been proposed based on convolutional neural network. FCN is the first fully convolutional network trained in an end-to-end and pixel-to-pixel way. It also presents the primitively encoder-decoder architecture in semantic segmentation, which is widely adopted in subsequent methods. To achieve higher accuracy, PSPNet utilizes a pyramid pooling module to aggregate global context and SFNet proposes a flow alignment module to strengthen the feature representations.

Yet, these models are not suitable for real-time applications because of their high computation cost. To accelerate the inference speed, Espnetv2 utilizes light-weight convolutions to extract features from an enlarged receptive field. BiSeNetV2 proposes bilateral segmentation network and extracts the detail features and semantic features separately. STDCSeg designs a new backbone named STDC to improve the computation efficiency. However, these models do not achieve satisfactory trade-off between accuracy and speed.

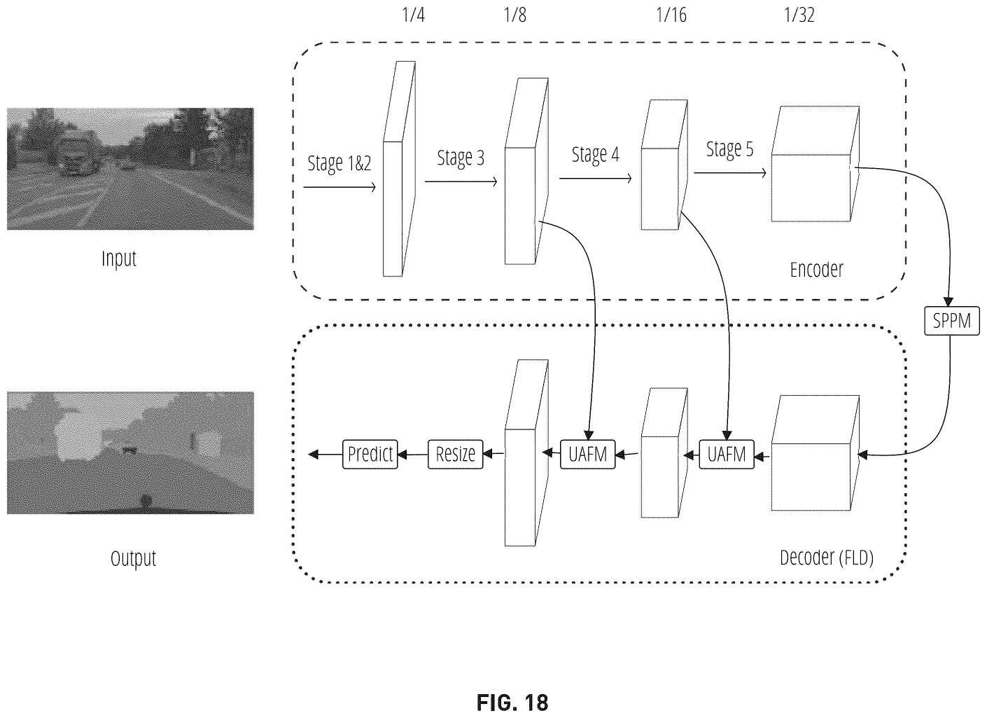

As illustrated in FIG. 18, PPLiteSeg adopts the encode-decoder architecture and consists of three novel modules: Flexible and Lightweight Decoder (FLD), Unified Attention Fusion Module (UAFM) and Simple Pyramid Pooling Module (SPPM). The motivations and details of these modules are introduced as follows.

The encoder in semantic segmentation models extracts hierarchical features, and the decoder fuses and unsamples features. For the features from low level to high level in encoder, the number of channels increases and the spatial size decreases, which is an efficient design. For the features from high level to low level in decoder, the spatial size increases, while the number of channels are the same in recent models. Therefore, a Flexible and Lightweight Decoder (FLD) is presented, which gradually reduces the channels and increases the spatial size for the features. Besides, the volume of proposed decoder can be easily adjusted according to the encoder. The flexible design balances the computation complexity of encoder and decoder, which makes the overall model more efficient.

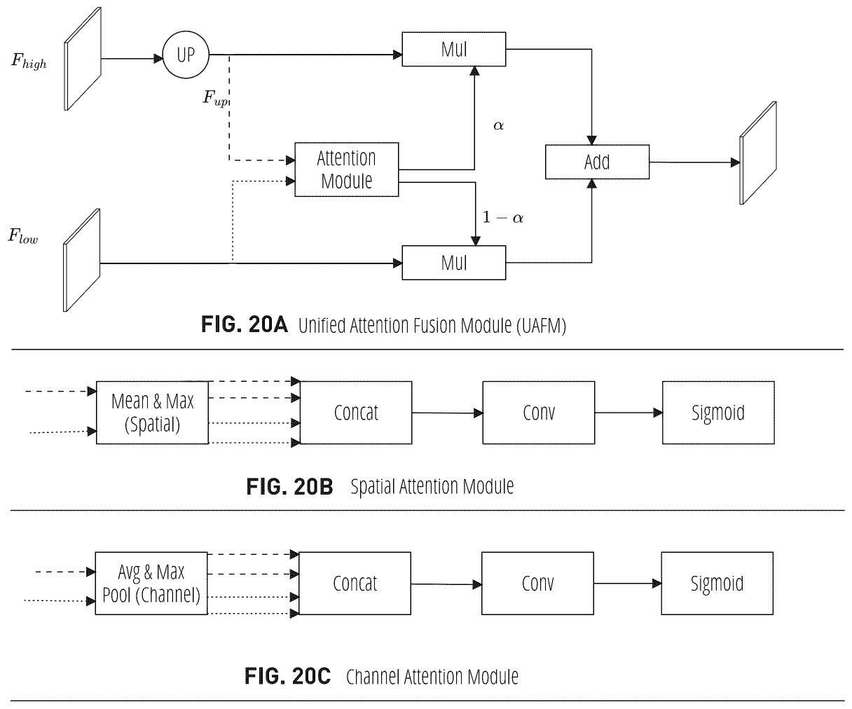

Strengthening feature representations is a crucial way to improve segmentation accuracy. It is usually achieved through fusing the low-level and high-level features in a decoder. However, the fusion modules in existing methods usually suffer from high computation cost. A Unified Attention Fusion Module (UAFM) is proposed to strengthen feature representations efficiently. As shown in FIG. 20A, UAFM first takes advantage of the attention module to produce weight α, and then fuses the input features with a. In UAFM, there are two kinds of attention modules, i.e. spatial and channel attention modules, which exploit inter-spatial and inter-channel relationships of the input features.

Contextual aggregation is another key to promote segmentation accuracy, but previous aggregation modules are time-consuming for real-time networks. Based on the framework of PPM, a Simple Pyramid Pooling Module (SPPM), which reduces the intermediate and output channels, removes the short-cut, and replaces the concatenate operation with an add operation. Experimental results show SPPM contributes to the segmentation accuracy with low computation cost.

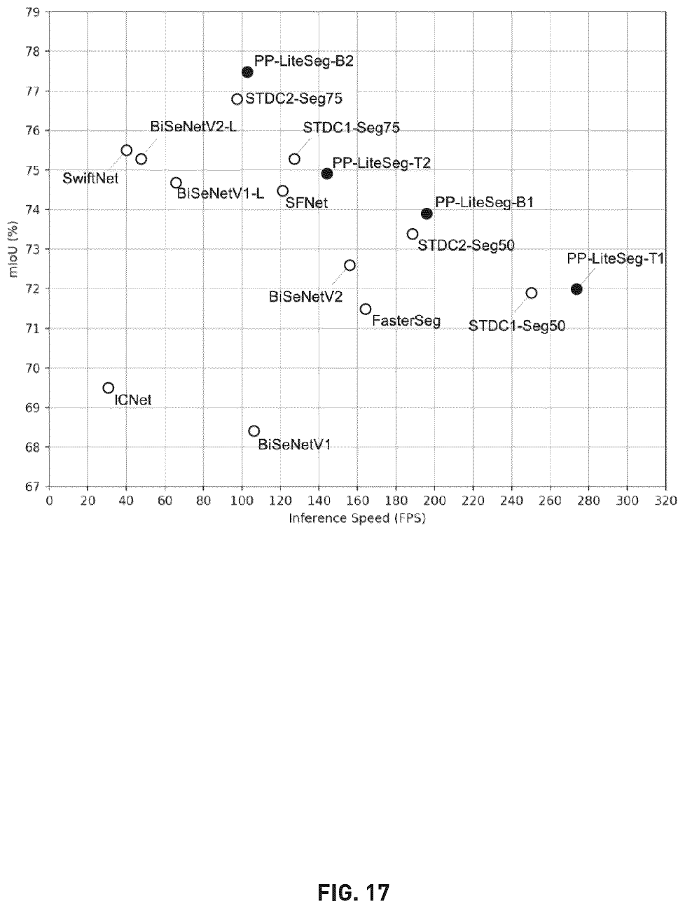

The proposed PP-LiteSeg were evaluated through extensive experiments on Cityscapes and Cam Vid dataset. As illustrated in FIG. 17, PP-LiteSeg achieves a superior tradeoff between segmentation accuracy and inference speed. Specifically, PP-LiteSeg achieves 72.0% mIoU/273.6 FPS and 77.5% mIoU/102.6 FPS on the Cityscapes test set.

### Semantic Segmentation

Deep learning has helped semantic segmentation make remarkable leap-forwards. FCN is the first full convolutional network for semantic segmentation. It is trained in an end-to-end and pixel-to-pixel way. Besides, images with arbitrary size can be segmented by FCN. Following the design of FCN, various methods have been proposed in later. Segnet applies the indices of max-pooling operation in encoder to upsampling operation in decoder. Therefore, the information in decoder is reused and the decoder produces refined features. PSPNet proposes the pyramid pooling module to aggregate local and global information, which is effective for segmentation accuracy. Besides, recent semantic segmentation methods utilize the transformer architecture to achieve better accuracy.

### Realtime Semantic Segmentation

To fulfill the real-time demands of semantic segmentation, lots of methods have been proposed, e.g., lightweight module design, dual-branch architecture, early-down sampling strategy, multiscale image cascade network. ENet uses an early-down sampling strategy to reduce the computation cost of processing large images and feature maps. For efficiency, ICNet designs a multi-resolution image cascade network. Based on bilateral segmentation network, Bisenet extracts the detail features and semantic features separately. The bilateral network is lightweight, so the inference speed is fast. STDCSeg proposes the channel-reduced receptive field-enlarged STDC module and designs an efficient backbone, which can strengthen the feature representations with low computation cost. To eliminate the redundancy in two-branch network, STDCSeg guides the features with detailed ground truth, so the efficiency is further improved. Espnetv2 uses group point-wise and depth-wise dilated separable convolutions to learn features from an enlarged receptive field in a computation friendly manner.

### Feature Fusion Module

The feature fusion module is commonly used in semantic segmentation to strengthen feature representations. In addition to the element-wise summation and concatenation methods, researchers propose several methods as follows. In BiSeNet, the BGA module employs element-wise mul method to fuse the features from the spatial and contextual branches. To enhance the features with high-level context, DFANet fuses features in a stage-wise and subnet-wise way. To tackle the problem of misalignment, SFNet and AlignSeg first learn the transformation offsets through a CNN module, and then apply the transformation offsets to grid sample operation to generate the refined feature. In detail, SFNet designs the flow alignment module. AlignSeg designs aligned feature aggregation module and the aligned context modeling module. FaPN solves the feature misalignment problem by applying the transformation offsets to deformable convolution.

### Flexible Lightweight Decoder

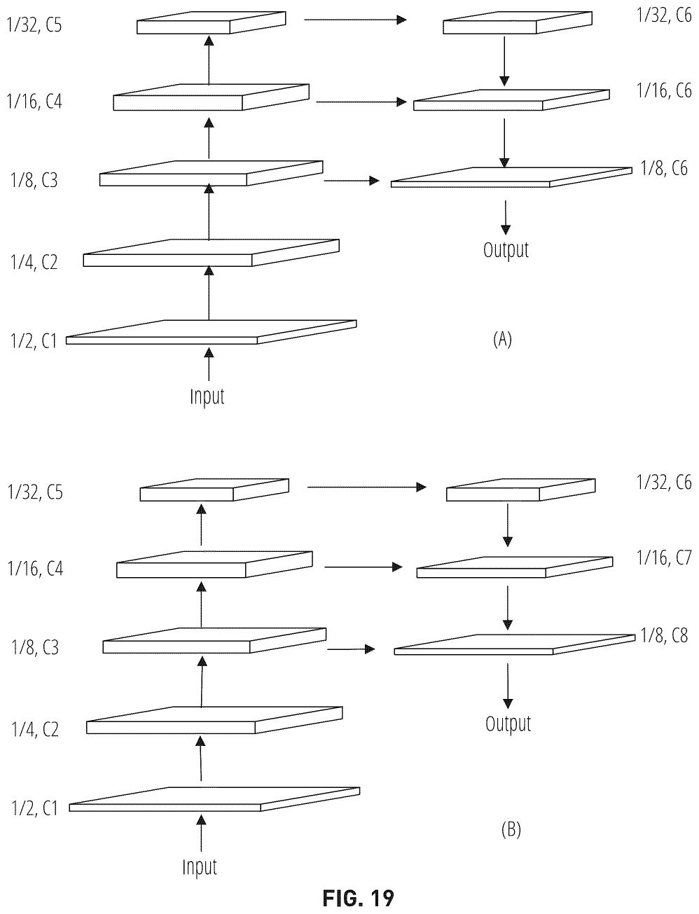

Encoder-decoder architecture has been proved to be effective for semantic segmentation. In general, the encoder utilizes a series of layers grouped into several stages to extract hierarchical features. For the features from low level to high level, the number of channels gradually increases and the spatial size of the features decreases. This design balances the computation cost of each stage, which ensures the efficiency of the encoder. The decoder also has several stages, which are responsible for fusing and up sampling features. Although the spatial size of features increases from high level to low level, the decoder in recent lightweight models keeps the feature channels the same in all levels. Therefore, the computation cost of shallow stage is much larger than that of the deep stage, which leads to the computation redundancy in shallow stage. To improve the efficiency of decoder, a Flexible and Lightweight Decoder (FLD) is presented. As illustrated in FIG. 19, FLD gradually decreases the channels of the features from high level to low level. FLD can easily adjusts the computation cost to achieve better balance between encoder and decoder. Although the channels of features in FLD are decreasing, the experiments show that PP-LiteSeg achieves competitive accuracy compared to other methods.

### Unified Attention Fusion Module

As discussed above, fusing multi-level features is essential to achieve high segmentation accuracy. In addition to the element-wise summation and concatenation methods, researchers propose several methods, e.g. SFNet, FaPN and AttaNet. A Unified Attention Fusion Module (UAFM) is proposed that applies channel and spatial attention to enrich the fused feature representations.

UAFM Framework. As illustrated in FIG. 20A, UAFM utilizes an attention module to produce the weight α, and fuses the input features with α by Mul and Add operations. In detail, the input features are denoted as F_{high} and F_{low}. F_{high} is the output of the deeper module, and F_{low} is the counterpart from the encoder. Note that they have same channels. UAFM first makes use of bilinear interpolation operation to upsample F_{high} to the same size of F_{low}, while the upsampled feature is denoted as Fᵤₚ. Then, the attention module takes Fᵤₚ and F_{low} as input and produces the weight α. Note that, the attention module can be a plugin, such as spatial attention module, channel attention module, etc. After that, to obtain attention-weighted features, the element-wise Mul operation is applied to Fᵤₚ and F_{low}, respectively. Finally, UAFM performs element-wise addition for the attention-weighted features and outputs the fused feature. The above procedure is formulated as equation 1.

$${F}_{up} = Upsample ( {F}_{high} ) \\ α = Attention ( {F}_{up} , {F}_{low} ) \\ {F}_{out} = {F}_{up} \cdot α + {F}_{low} \cdot ( 1 - α ) \qquad Equation 1$$

Spatial Attention Module. The motivation of the spatial attention module is exploiting the inter-spatial relationship to produce a weight, which represents the importance of each pixel in the input features. As shown in FIG. 20B, given the input features, i.e., Fᵤₚ∈R^{C×H×W} and F_{low}∈R^{C×H×W}, perform mean and max operations along the channel axis to generates four features, of which the dimension is R^{1×H×W}. Afterwards, these four features are concatenated to a feature F_{cat}∈R^{4×H×W}. For the concatenated feature, the convolution and sigmoid operations are applied to output α∈R^{1×H×W}. The formulation of the spatial attention module is shown in equation 2. Furthermore, the spatial attention module can be flexible, e.g. removing the max operation to reduce computation cost.

$${F}_{cat} = Concat ( Mean ( {F}_{up} ) , Max ( {F}_{up} ) , \\ Mean ( {F}_{low} ) , Max ( {F}_{low} ) ) \\ α = Sigmoid ( Conv ( {F}_{cat} ) ) \qquad Equation 2$$

$${F}_{cat} = Concat ( AvgPool ( {F}_{up} ) , Max Pool ( {F}_{up} ) , \\ AvgPool ( {F}_{low} ) , Max Pool ( {F}_{low} ) ) \\ α = Sigmoid ( Conv ( {F}_{cat} ) ) \qquad Equation 3$$

Channel Attention Module. The key concept of the channel attention module is leveraging the inter-channel relationship to generate a weight, which indicates the importance of each channel in the input features. As shown in FIG. 20C, the proposed channel attention module utilizes average-pooling and max-pooling operations to squeeze the spatial dimension of input features. This procedure generates four features with the dimension R^{C×1×1}. Then, it concatenates these four features along the channel axis and performs convolution and sigmoid operations to produce a weight α∈R^{C×1×1}. In short, the procedures of the channel attention module can be formulated as equation 3.

### Simple Pyramid Pooling Module

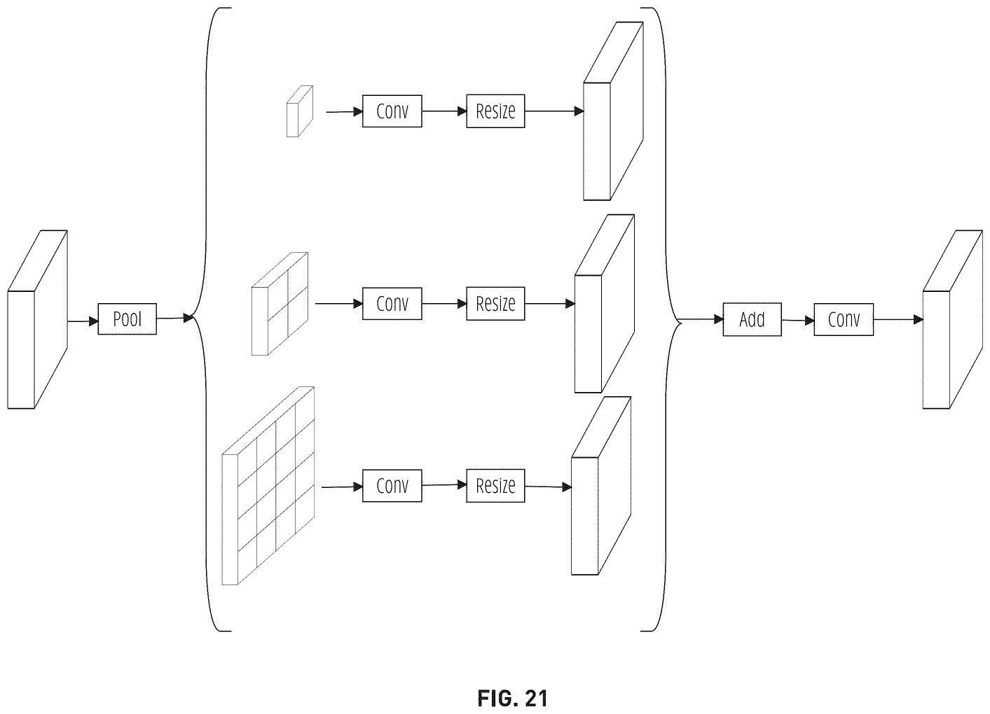

FIG. 21 illustrates a proposed Simple Pyramid Pooling Module (SPPM). It first leverages the pyramid pooling module to fuse the input feature. The pyramid pooling module has three global-average-pooling operations and the bin sizes are 1×1, 2×2, and 4×4 respectively. Afterwards, the output features are followed by the convolution and up sampling operations. For the convolution operation, the kernel size is 1×1 and the output channel is smaller than the input channel. Finally, up sampled features are added up and applied to a convolution operation to produce the refined feature. Compared to original PPM, SPPM reduces the intermediate and output channels, removes the short-cut, and replaces the concatenate operation with an addition operation. Consequently, SPPM is more efficient and suitable for real-time models.

### Network Architecture

TABLE 1

| Model | Encoder | Channels in Decoder |
|---|---|---|
| PP-LiteSeg-T | STDC1 | 32, 64, 128 |
| PP-LiteSeg-B | STDC2 | 64, 96, 128 |

The architecture of the proposed PP-LiteSeg is demonstrated in FIG. 18. PP-LiteSeg mainly comprises three modules: encoder, aggregation and decoder.

Firstly, given an input image, PP-Lite utilizes a common lightweight network as encoder to extract hierarchical features. In detail, the STDCNet is chosen for its outstanding performance. The STDCNet has 5 stages, the stride for each stage is 2, so the final feature size is 1/32 of the input image. As shown in Table 1, two versions of PP-LiteSeg are presented, i.e., PP-LiteSeg-T and PP-LiteSeg-B, of which the encoder is STDC1 and STDC2 respectively. The PPLiteSeg-B achieves higher segmentation accuracy, while the inference speed of PP-LiteSeg-T is faster. It is worth noting that the SSLD method is applied to the training of the encoder and obtain enhanced pre-trained weights, which is beneficial for the convergence of segmentation training.

Secondly, PP-LiteSeg adopts SPPM to model the longrange dependencies. Taking the output feature of the encoder as input, SPPM produces a feature that contains global context information.

Finally, PP-LiteSeg utilizes proposed FLD to gradually fuse multi-level features and output the resulting image. Specifically, FLD consists of two UAFM and a segmentation head. For efficiency, the spatial attention module is utilized in UAFM. Each UAFM takes two features as input, i.e., a low-level feature extracted by the stages of the encoder, a high-level feature generated by SPPM or the deeper fusion module. The latter UAFM outputs fused features with the down-sample ratio of 1/8. In the segmentation head, Conv-BN-Relu operation are performed to reduce the channels of the 1/8 down-sample feature to the number of classes. An upsampling operation is followed to expand the feature size to the input image size, and an argmax operation predicts the label of each pixel. The cross entropy loss with Online Hard Example Mining is adopted to optimize the models.

### Datasets and Implementation Details

Cityscapes. The Cityscapes is a large-scale dataset for urban segmentation. It contains 5,000 fine annotated images, which are further split into 2975, 500, and 1525 images for training, validation and testing, respectively. The resolution of the images is 2048×1024, which poses great challenges for the real-time semantic segmentation methods. The annotated images have 30 classes and the experiments only use 19 classes for a fair comparison with other methods.

CamVid. Cambridge-driving Labeled Video Database (CamVid) is a small-scale dataset for road scene segmentation. There are 701 images with high-quality pixel level annotations, in which 367, 101 and 233 images are chosen for training, validation and testing respectively. The images have the same resolution of 960×720. The annotated images provide 32 categories, of which the subset of 11 categories are used in the experiments.

Training Settings. Following the common setting, the stochastic gradient descent (SGD) algorithm with 0.9 momentum is chosen as an optimizer. A warm-up strategy and the “poly” learning rate scheduler was also adopted. For Cityscapes, the batch size is 16, the max iterations are 160,000, the initial learning rate is 0.005, and the weight decay in the optimizer is 5e⁻⁴. For Cam Vid, the batch size is 24, the max iterations is 1,000, the initial learning rate is 0.01, and the weight decay is 1e⁻⁴. For data augmentation, random scaling, random cropping, random horizontal flipping, random color jittering and normalization may be utilized. The random scale ranges in [0.125, 1.5], [0.5, 2.5] for Cityscapes and Camvid respectively. The cropped resolution of Cityscapes is 1024×512, and the cropped resolution of CamVid is 960×720. All of the experiments are conducted on Tesla V100 GPU using PaddlePaddle1. Code and pretrained models are available at PaddleSeg2.

Inference Settings. For a fair comparison, PPLiteSeg was exported to ONNX and utilize TensorRT to execute the model. Similar to other methods, an image from Cityscapes is first resized to 1024×512 and 1536×768, then the inference model takes the scaled image and produces the predicted image, finally, the predicted image is resized to the original size of the input image. The cost of the three steps is counted as the inference time. For Cam Vid, the inference model takes the original image as input, while the resolution is 960×720. All inference experiments were conducted under CUDA 10.2, CUDNN 7.6, TensorRT 7.1.3 on NVIDIA 1080Ti GPU. The standard mIoU for segmentation accuracy comparison and FPS for inference speed comparison was employed.

TABLE 2

| | | | mIoU (%) | | |
|---|---|---|---|---|---|
| Model | Encoder | Resolution | val | test | FPS |
| ENet | — | 512 × 1024 | — | 58.3 | 76.9 |
| ICNet | PSPNet50 | 1024 × 2048 | — | 69.5 | 30.3 |
| ESPNet | ESPNet | 512 × 1024 | — | 60.3 | 112.9 |
| ESPNetV2 | ESPNetV2 | 512 × 1024 | 66.4 | 66.2 | — |
| SwiftNet | ResNet18 | 1024 × 2048 | 75.4 | 75.5 | 39.9 |
| BiSeNetV1 | Xception39 | 768 × 1536 | 69.0 | 68.4 | 105.8 |
| BiSeNetV1-L | ResNet18 | 768 × 1536 | 74.8 | 74.7 | 65.5 |
| BiSeNetV2 | — | 512 × 1024 | 73.4 | 72.6 | 156 |
| BiSeNetV2-L | — | 512 × 1024 | 75.8 | 75.3 | 47.3 |
| FasterSeg | — | 1024 × 2048 | 73.1 | 71.5 | 163.9 |
| SFNet | DF1 | 1024 × 2048 | — | 74.5 | 121 |
| STDC1-Seg50 | STDC1 | 512 × 1024 | 72.2 | 71.9 | 250.4 |
| STDC2-Seg50 | STDC2 | 512 × 1024 | 74.2 | 73.4 | 188.6 |
| STDC1-Seg75 | STDC1 | 768 × 1536 | 74.5 | 75.3 | 126.7 |
| STDC2-Seg75 | STDC2 | 768 × 1536 | 77.0 | 76.8 | 97.0 |
| PP-LiteSeg-T1 | STDC1 | 512 × 1024 | 73.1 | 72.0 | 273.6 |
| PP-LiteSeg-B1 | STDC2 | 512 × 1024 | 75.3 | 73.9 | 195.3 |
| PP-LiteSeg-T2 | STDC1 | 768 × 1536 | 76.0 | 74.9 | 143.6 |
| PP-LiteSeg-B2 | STDC2 | 768 × 1536 | 78.2 | 77.5 | 102.6 |

Comparisons with State-of-the-Arts

With the training and inference setting mentioned above, the proposed PP-LiteSeg was compared with previous state of the art real-time models on Cityscapes. For fair comparison, PP-LiteSeg-T and PP-LiteSeg-B were evaluated at two resolutions, i.e., 512×1024 and 768×1536. Table 2 shows the comparisons with state-of-the-art real-time methods on Cityscapes. The training and inference setting refer to the implementation details and presents the model information, input resolution, mIoU, and FPS of various approaches. FIG. 17 provides an intuitive comparison of segmentation accuracy and inference speed. The experimental evaluations demonstrate that the proposed PP-LiteSeg achieves a state-of-the-art trade-off between accuracy and speed against other methods. Specifically, PP-LiteSeg-T1 is observed to achieve 273.6 FPS and 72.0% mIoU, which means the fastest inference speed and competitive accuracy. With the resolution of 768×1536, PPLiteSeg-B2 achieves the best accuracy, i.e. 78.2% mIoU for the validation set, 77.5% mIoU for the test set. In addition, with same encoder and input resolution as STDC-Seg, PPLiteSeg shows better performance.

TABLE 3

| Model | FLD | SPPM | UAFM | mIoU(%) | FPS |
|---|---|---|---|---|---|
| Baseline | | | | 77.50 | 110.9 |
| PP-LiteSeg-B2 | ✓ | | | 77.67 | 109.7 |
| PP-LiteSeg-B2 | ✓ | ✓ | | 77.76 | 106.3 |
| PP-LiteSeg-B2 | ✓ | | ✓ | 77.89 | 105.5 |
| PP-LiteSeg-B2 | ✓ | ✓ | ✓ | 78.21 | 102.6 |

### Ablation Study

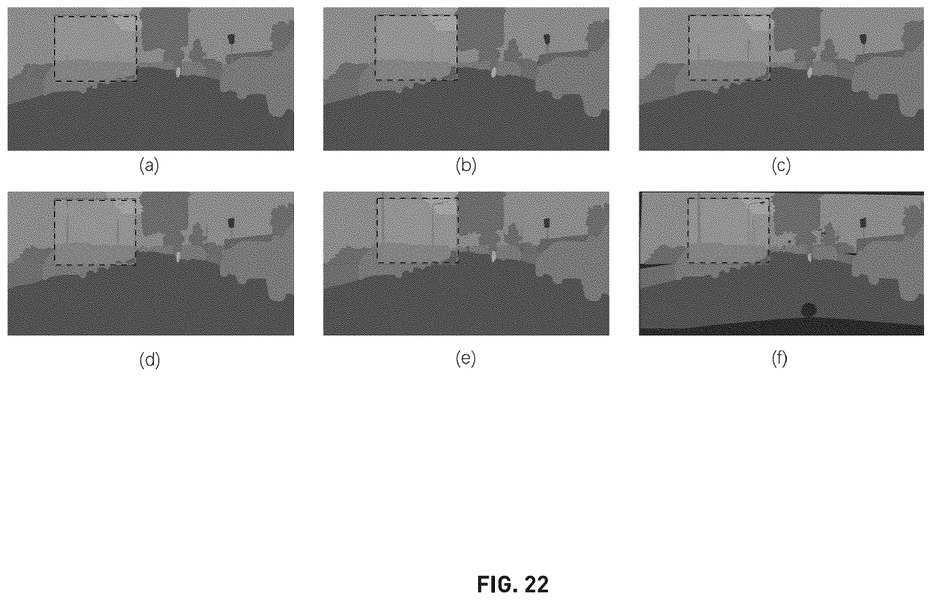

Ablation experiments are conducted to demonstrate the effectiveness of the proposed modules. The experiments choose PP-LiteSeg-B2 in the comparison and use the same training and inference setting. The baseline model is the PP-LiteSeg-B2 without the proposed modules, while the number of features channels is 96 in decoder and the fusion method is element-wise summation. Table 3 presents the quantitative results of the ablation study. It can be found that the FLD in PP-LiteSeg-B2 improves the mIoU by 0.17%. Adding SPPM and UAFM also improve the segmentation accuracy, while the inference speed slightly decreases. Based on three proposed modules, PP-LiteSeg-B2 achieves 78.21 mIoU with 102.6 FPS. The mIOU is boosted by 0.71% compared to the baseline model. FIG. 22 provides the qualitative comparisons. It is observed that the predicted image becomes more consistent with the ground truth when adding FLD, SPPM and UAFM one by one. In short, the proposed modules are effective for semantic segmentation.

TABLE 4

| Model | Encoder | mIoU (%) | FPS |
|---|---|---|---|
| ENet | — | 51.3 | 61.2 |
| ICNet | PSPNet50 | 67.1 | 34.5 |
| DFANet A | Xception A | 64.7 | 120 |
| SwiftNet | ResNet18 | 72.58 | — |
| BiSeNetV1 | Xception39 | 65.6 | 175 |
| BiSeNetV1-L | ResNet18 | 68.7 | 116.3 |
| BiSeNetV2 | — | 72.4 | 124.5 |
| BiSeNetV2-L | — | 73.2 | 32.7 |
| STDC1-Seg | STDC1 | 73.0 | 197.6 |
| STDC2-Seg | STDC2 | 73.9 | 152.2 |
| PP-LiteSeg-T | STDC1 | 73.3 | 222.3 |
| PP-LiteSeg-B | STDC2 | 75.0 | 154.8 |

### Experiments on CamVid

To further demonstrate the capability of PP-LiteSeg, experiments were also conducted on the Cam Vid dataset. Similar to other works, the input resolution for training and inference is 960×720. As shown in Table 4, PP-LiteSeg-T achieves 222.3 FPS, which is over 12.5% faster than other methods. PP-LiteSeg-B achieves the best accuracy, i.e., 75.0% mIoU with 154.8 FPS. Overall, the comparisons show PP-LiteSeg achieves a state-of-the-art trade-off between accuracy and speed on Camvid.

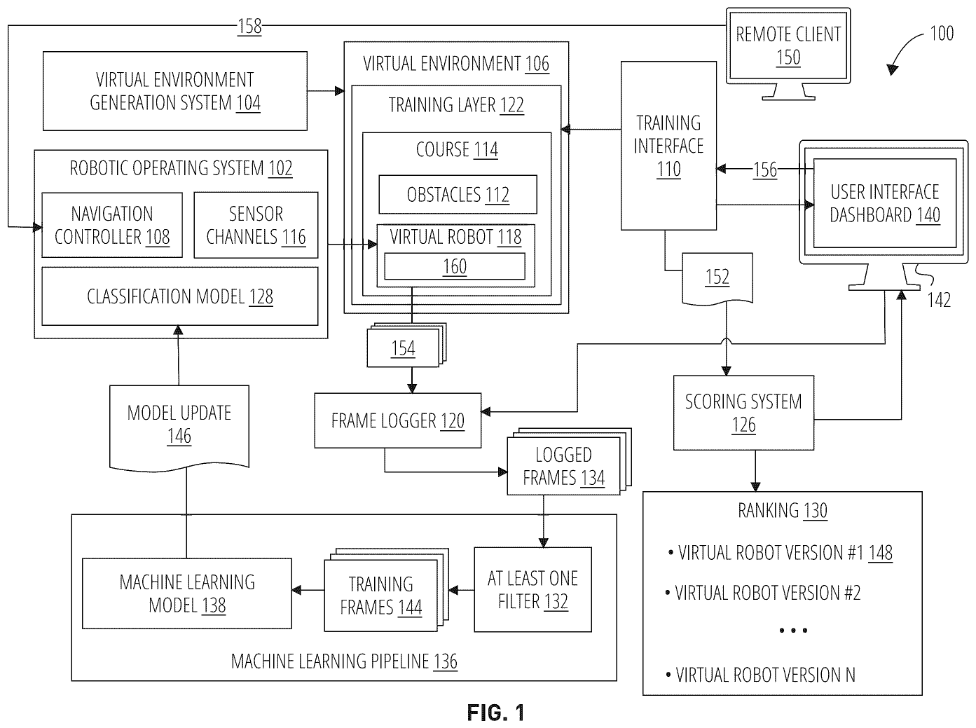

FIG. 1 illustrates a system 100 in accordance with one embodiment. The system 100 comprises a a virtual environment generation system 104, a robotic operating system 102, a training interface 110, and a machine learning pipeline 136. The virtual environment generation system 104 generates a virtual environment 106 that includes a course 114 with an obstacles 112. The robotic operating system 102 comprises a navigation controller 108, sensor channels 116, and classification model 128 and is utilized to generate a virtual robot 118 in the virtual environment 106. The virtual robot 118 is configured to travel through the course 114 of the virtual environment 106. The training interface 110 comprises a training layer 122, a scoring system 126, a user interface dashboard 140, and a frame logger 120. The training layer 122 receives testing configurations 156 from the user interface dashboard 140 to configure the course 114 such as the difficulty and the number of obstacles 112 presented to the robot. The testing configurations 156 may also include changes in the lighting and other environmental changes. The user interface dashboard 140 is displayed on a user display 142 and shows different user interfaces to a user for configuring testing scenarios for the virtual robot 118. The scoring system 126 ranks versions of the virtual robot 118 based metrics for completing the course 114 and interactions with obstacles 112. During training scenario, where the virtual robot 118 is navigating through the course 114, the frame logger 120 may be capture frames 154 viewed through the sensor channels 116 of the virtual robot 118. The frames 154 are virtual frames and may include numerous views from virtualized cameras of the virtual robot 118. The frame logger 120 captures these frames 154 as logged frames 134 and communicates them to a machine learning pipeline 136. The machine learning pipeline 136 applies an at least one filter 132 changing to the logged frames 134 to generate training frames 144. The at least one filter 132 may simulate variations in image quality, lens interferences, light intensity, light source location, surface texture, surface color, surface pattern, and surface reflectivity. The training frames 144 are then utilized to retrain a machine learning model 138 to generate a model update 146. The model update 146 is then utilized to update the classification model 128 generating a new virtual robot version. The new virtual robot version can then be tested in the virtual environment 106. Different versions of the virtual robot 118 may be ranked based on their navigation score 152. The navigation score 152 may be utilized to generate the ranking 130 displaying a ranked list of different virtual robot versions 148 that are visible in the user interface dashboard 140. The navigation controller 108 may be configured with navigation instructions 158 from a remote client 150.

In an embodiment, the system 100 operates a virtual environment generation system 104 configured to render a virtual environment 106 including a course 114 and obstacles 112. The system 100 configures a robotic operating system 102 including a navigation controller 108, a classification model 128, and sensor channels 116 to operate as a virtual robot version 148 in the virtual environment 106. The system 100 operates a training interface 110 configured to observe, configure, and record interactions between the virtual robot 118 and the virtual environment 106, where the training interface 110 includes a user interface dashboard 140, a training layer 122, a frame logger 120, and a scoring system 126. The system 100 operates the training layer 122 to adjust the complexity of the course 114 and types and quantity of the obstacles 112 presented to the virtual robot 118 in the virtual environment 106 configured by the testing configurations 156 from the user interface dashboard 140. The system 100 operates the movement of the virtual robot 118 in the virtual environment 106 by way of a navigation controller 108 to traverse through the course 114. The system 100 logs frames 154 from the sensor channels 116 of the virtual robot 118 while navigating through the course 114 and the obstacles 112 through operation of the frame logger 120. The system 100 determines a navigation score 152 for the virtual robot 118 on interactions on the course 114 through operation of the scoring system 126. The system 100 communicates logged frames 134 to a machine learning pipeline 136 and applies at least one filter 132 to the logged frames 134 to generate training frames 144 for a machine learning model 138. The system 100 retrains the machine learning model 138 with the training frames 144 to generate a model update 146 for the classification model 128. The system 100 applies the model update 146 to the classification model 128 and generates a new virtual robot version. The system 100 ranks different virtual robot versions 148 based on the navigation score 152.

In an embodiment, the sensor channels 116 are image feeds of the virtual environment 106 captured by virtualized cameras 160 of the virtual robot 118.

In an embodiment, the frame logger 120 captures an array of images from the sensor channels 116.

In an embodiment, the at least one filter 132 is utilized to simulate variations in image quality, lens interferences, light intensity, light source location, surface texture, surface color, surface pattern, and surface reflectivity.

In an embodiment, the machine learning model 138 is a convolutional neural network for object classification.

In an embodiment, the frame logger 120 is controlled by inputs from the user interface dashboard 140.

In an embodiment, the navigation controller 108 is configured by navigation instructions 158.

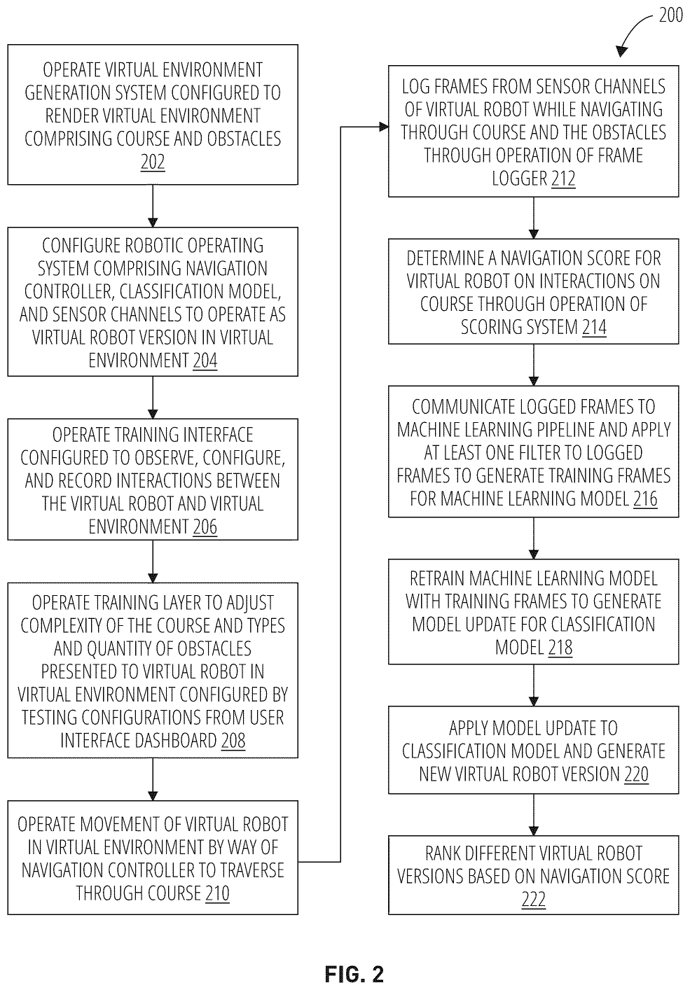

FIG. 2 illustrates a block diagram of a routine 200. In block 202, the routine 200 operates a virtual environment generation system configured to render a virtual environment comprising a course and obstacles. In block 204, the routine 200 configures a robotic operating system comprising a navigation controller, a classification model, and sensor channels to operate as a virtual robot version in the virtual environment. In block 206, the routine 200 operates a training interface configured to observe, configure, and record interactions between the virtual robot and the virtual environment, wherein the training interface comprises a user interface dashboard, a training layer, a frame logger, and a scoring system. In block 208, the routine 200 operates the training layer to adjust the complexity of the course and types and quantity of the obstacles presented to the virtual robot in the virtual environment configured by the testing configurations from the user interface dashboard. In block 210, the routine 200 operates the movement of the virtual robot in the virtual environment by way of a navigation controller to traverse through the course. In block 212, the routine 200 logs frames from the sensor channels of the virtual robot while navigating through the course and the obstacles through operation of the frame logger. In block 214, the routine 200 determines a navigation score for the virtual robot on interactions on the course through operation of the scoring system. In block 216, the routine 200 communicates logged frames to a machine learning pipeline and applies at least one filter to the logged frames to generate training frames for a machine learning model. In block 218, the routine 200 retrains the machine learning model with the training frames to generate a model update for the classification model. In block 220, the routine 200 applies the model update to the classification model and generates a new virtual robot version. In block 222, routine 200 ranks different virtual robot versions based on the navigation score.

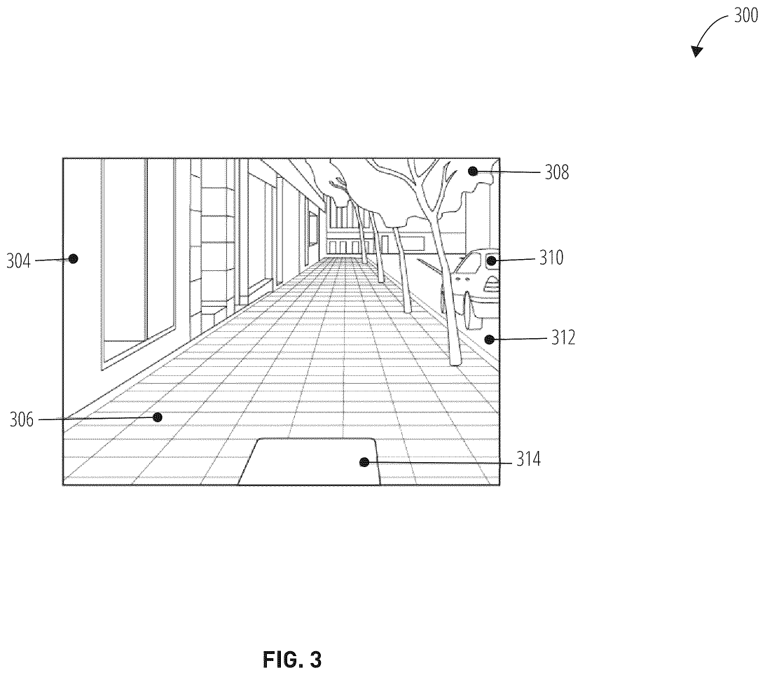

FIG. 3 illustrates a frame 300 of the virtual environment captured through the sensor channels of the virtual robot. The frame 300 depicts the virtual robot 314 and a virtual environment comprising a building 304, a sidewalk 306, a tree 308, a car 310, and a road 312.

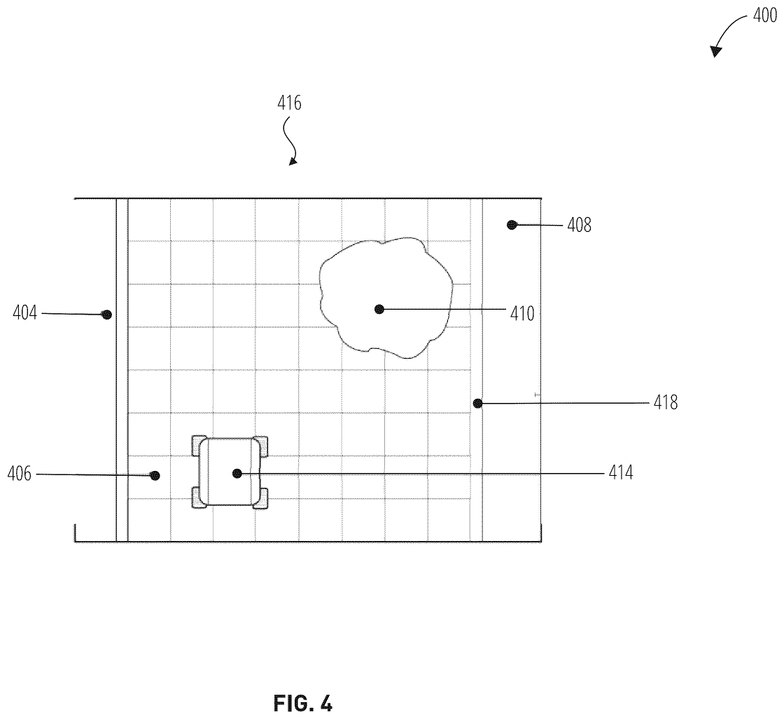

FIG. 4 illustrates top down view 400 of the virtual robot 414 in a virtual environment 416. In the view 400, the virtual environment 416 is shown with a building 404, sidewalk 406, a road 408, a tree 410, and a curb 418.

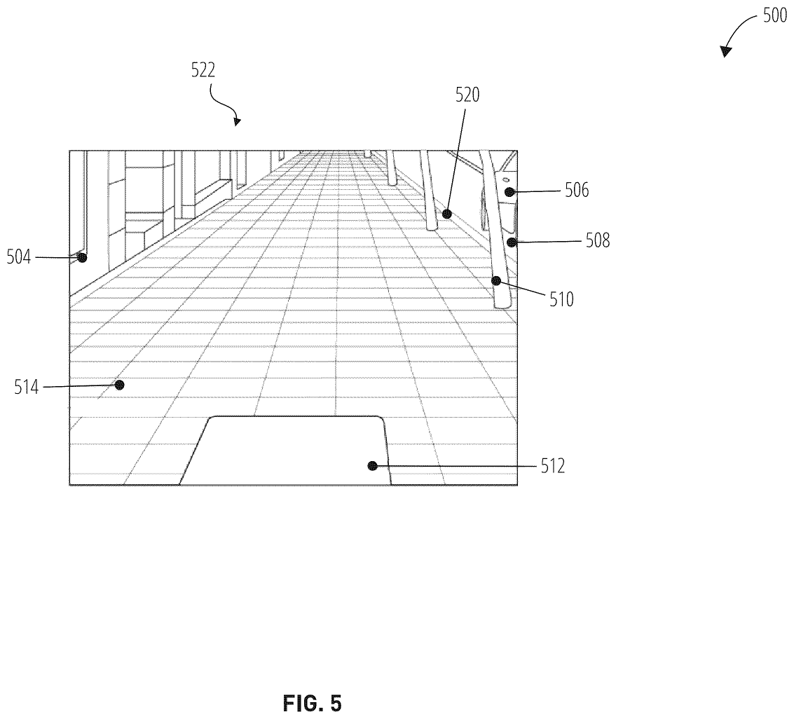

FIG. 5 illustrates a frame 500 of the virtual robot 512 in the virtual environment 522. The frame 500 is captured through sensor channels that collected visual data from virtualized cameras of the virtual robot 512. In the frame 500, the virtual environment 522 includes building 504, a car 506, a sidewalk 514, a road 508, a tree 510, and a curb 520.

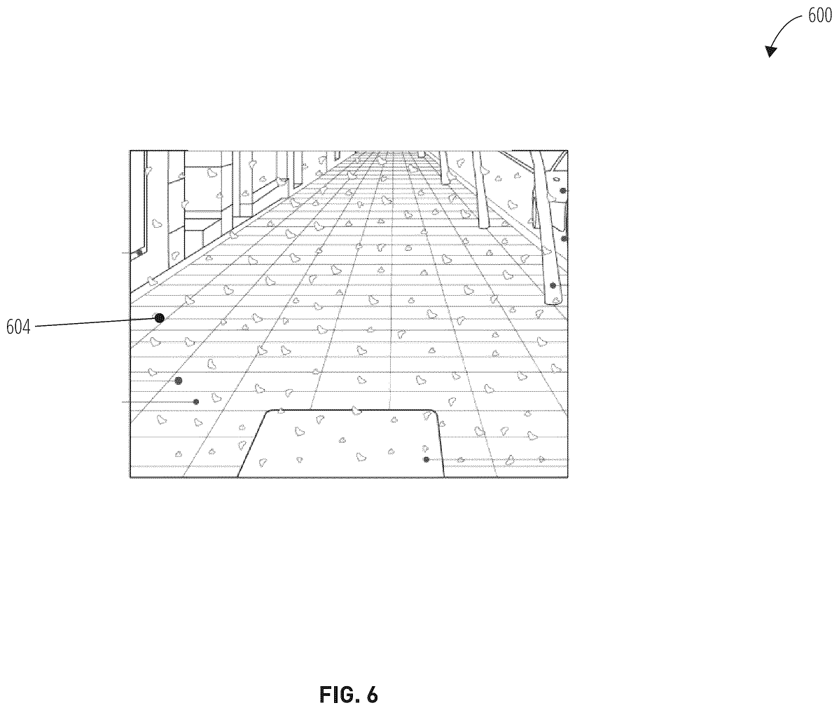

FIG. 6 illustrates a training frame 600 with a filter applied distorting the image. The training frame 600 is generated from the frame 500 that had at least one filter applied to it. The at least one filter gives the appearance that the camera lens is dirty or damaged that is accomplished by debris 604 in the frame.

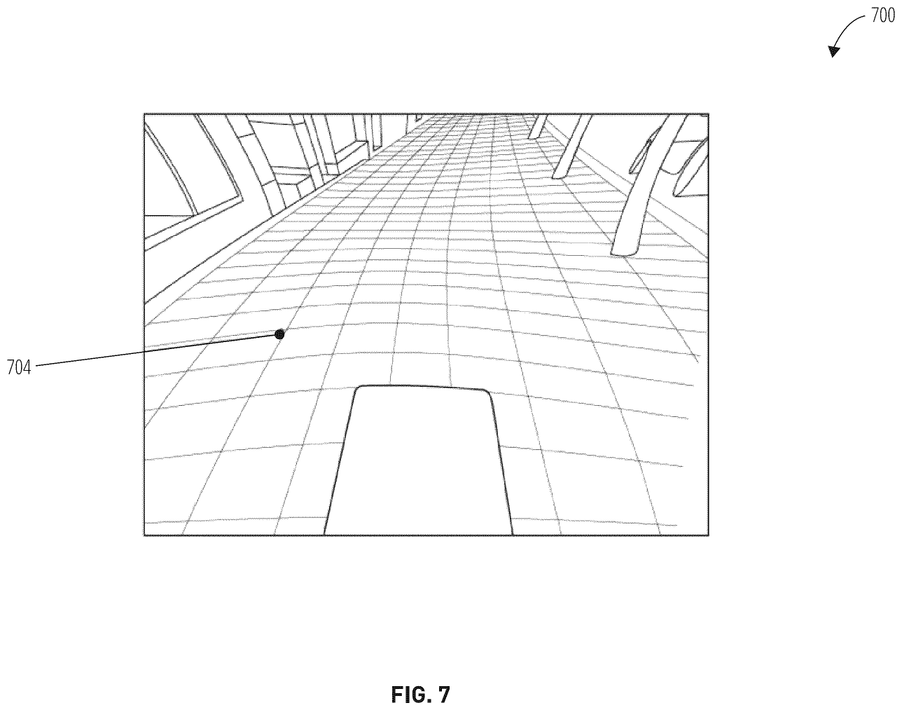

FIG. 7 illustrates a training frame 700 with a filter applied distorting the image. The training frame 700 is generated from the frame 500 with at least one filter applied. The at least one filter is a lens distortion 704 showing the sidewalk with improbable curvatures. The distortion 704 may represent water, oil, or another liquid droplet on the lens distorting the image.

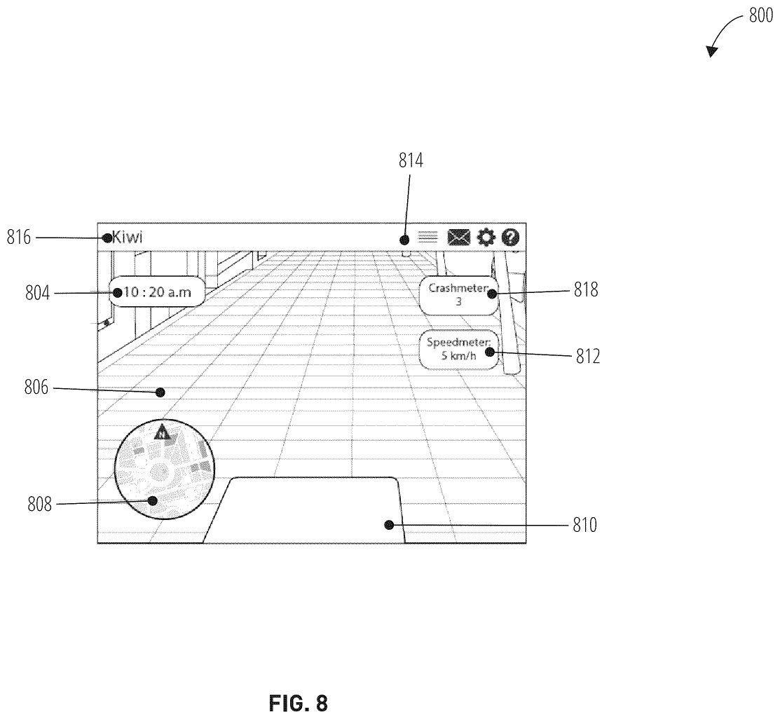

FIG. 8 illustrates a driver interface 800 in accordance with one embodiment. The driver interface 800 is provided as an overlay to sensor channels view of the virtual robot and utilized in combination with a remote operated for the virtual robot. The driver interface 800 comprises a settings 816, a clock 804, additional options 814, crash counter 818, and a speedometer 812. The driver interface 800 is overlayed above the view of the virtual environment and shows the sidewalk 806 and the virtual robot 810. The navigation view 808 may provide navigation assistance to a operator letting them know where the next point is in a course and where the layout virtual environment. The settings 816 may open up settings on the user interface dashboard for changing testing configurations. The crash counter 818 may record crashes with obstacles in the virtual environment. The additional options 814 may provide access to changing between views of the virtual robot or adjusting settings for controlling the robot such as sensitivity.

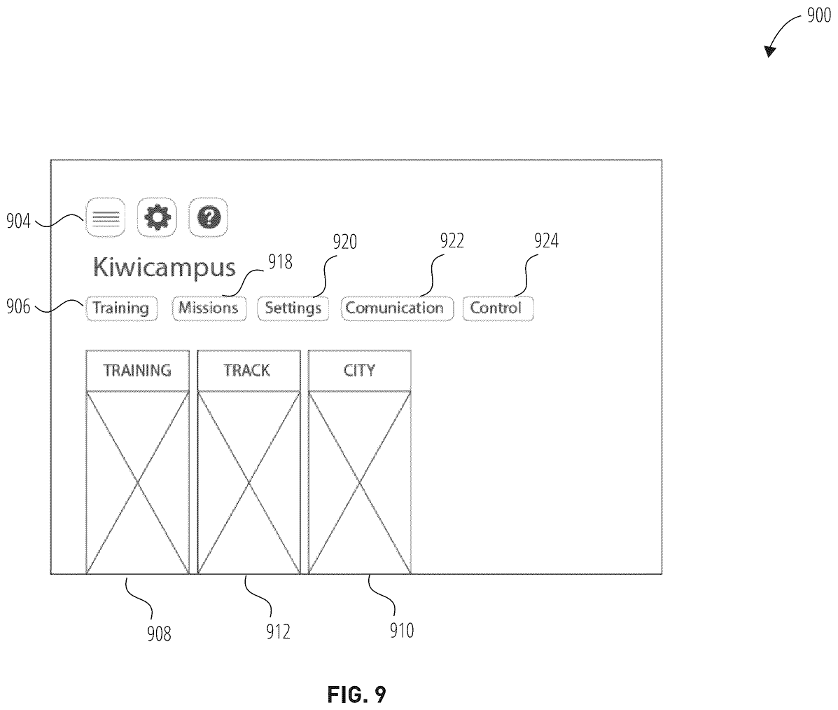

FIG. 9 illustrates a user interface 900 in accordance with one embodiment. The user interface 900 is a view of the user interface dashboard setting testing configurations. The user interface 900 shows settings 904 which are non training specific settings such as user profile or account management. The testing configurations include control settings 924, communication settings 922, mission settings 920, mission parameter 918, and training options 906. The control settings 924 provide a user with different control schemes and/or input device specific options such as key binds and acceleration. The communication settings 922 may include settings for responsiveness and virtualization of communication methods such as wifi, cellular, etc. The mission settings 920 are settings for the environment such as time of day or weather conditions. The mission parameter 918 are settings such as delivery and pick up locations. The training options 906 are settings for obstacles, such as obstructions, people, cars, crosswalks, and etc., The user interface dashboard may also include testing configurations for selecting the type of course that the virtual robot navigates through, the first may be a training course 908 with simple navigation instruction for going between two locations. The track course 912 may include obstacles or features such as a sidewalks or cross walks that the virtual robot needs to cross in addition to performing a pick up and drop off delivery. The city course 910 may include a virtualized city scape with moving obstacles such as people and cars and require navigating through streets to perform pickup and drop offs.

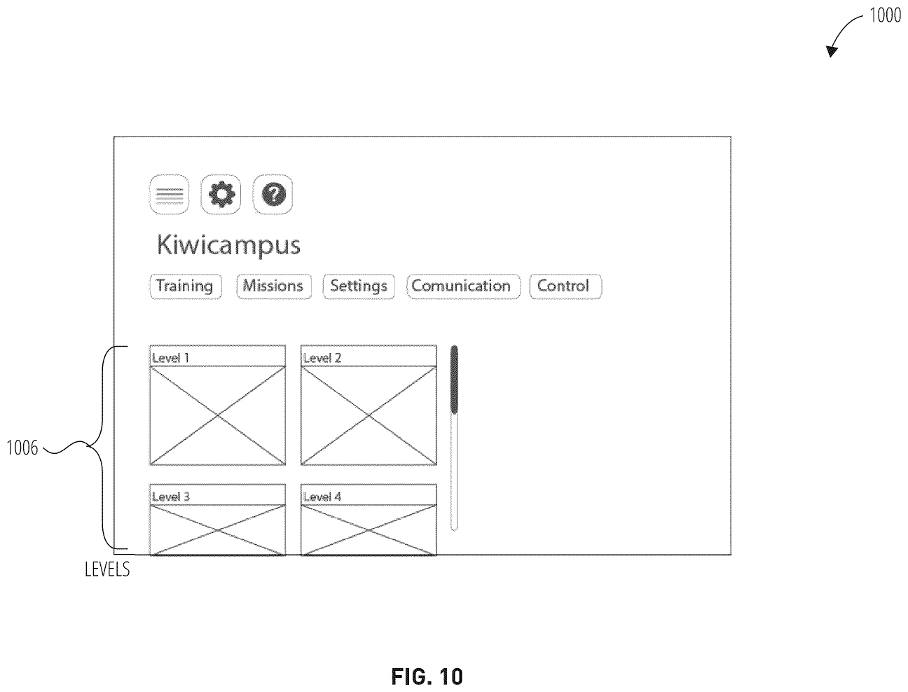

FIG. 10 illustrates a user interface 1000 in accordance with one embodiment. The user interface 1000 is a view of a user interface dashboard showing different levels 1006 for the courses. The different level may have different predefined settings or conditions are set by the different testing configurations.

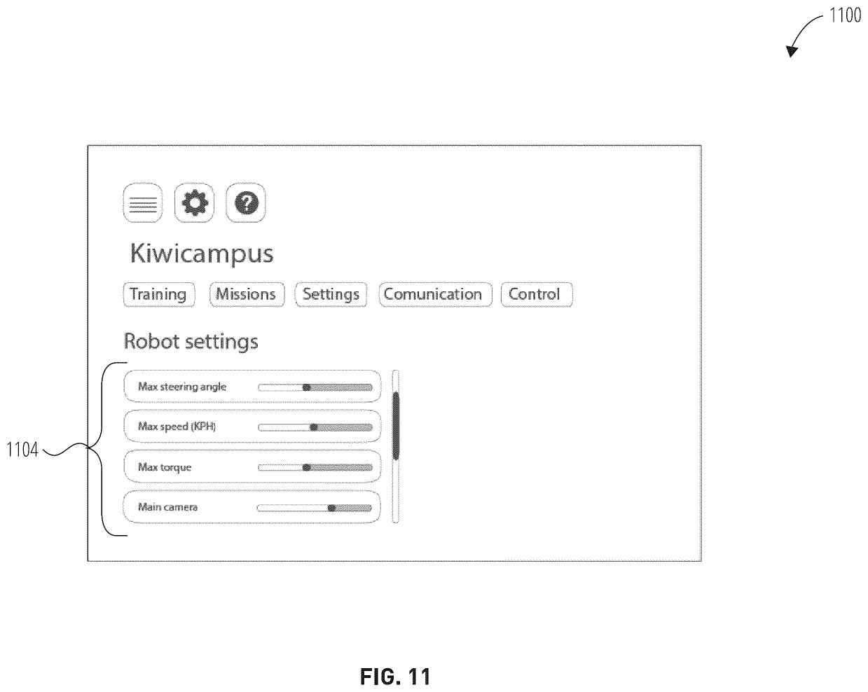

FIG. 11 illustrates a user interface 1100 in accordance with one embodiment. The user interface 1100 shows the user interface dashboard with robot settings 1104 that include settings for steering angle of the virtual robot, maximum speed of the virtual robot, the maximum torque of the virtual robot, and main camera adjustments. Additional settings may be provided and adjusted as part of the testing configurations.

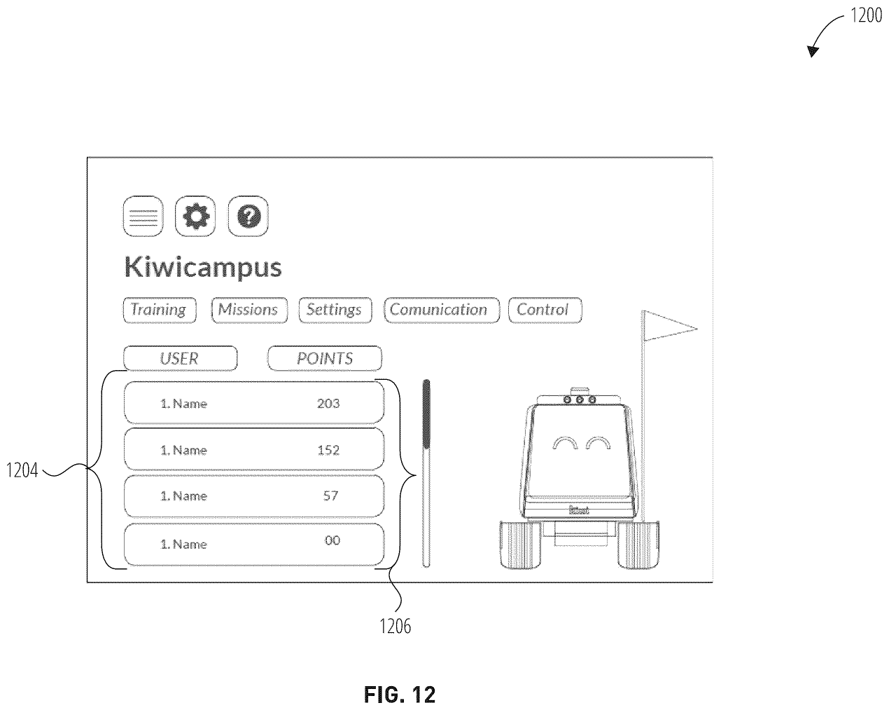

FIG. 12 illustrates a user interface 1200 in accordance with one embodiment. The user interface 1200 displays ranking 1204 for different operators of the virtual robot as well as accompanied navigation scores 1206. In an embodiment, the navigation scores 1206 may be utilized to rank different version of the virtual robot that are operating autonomously. Based on the speed, mission completion, and crash avoidance.

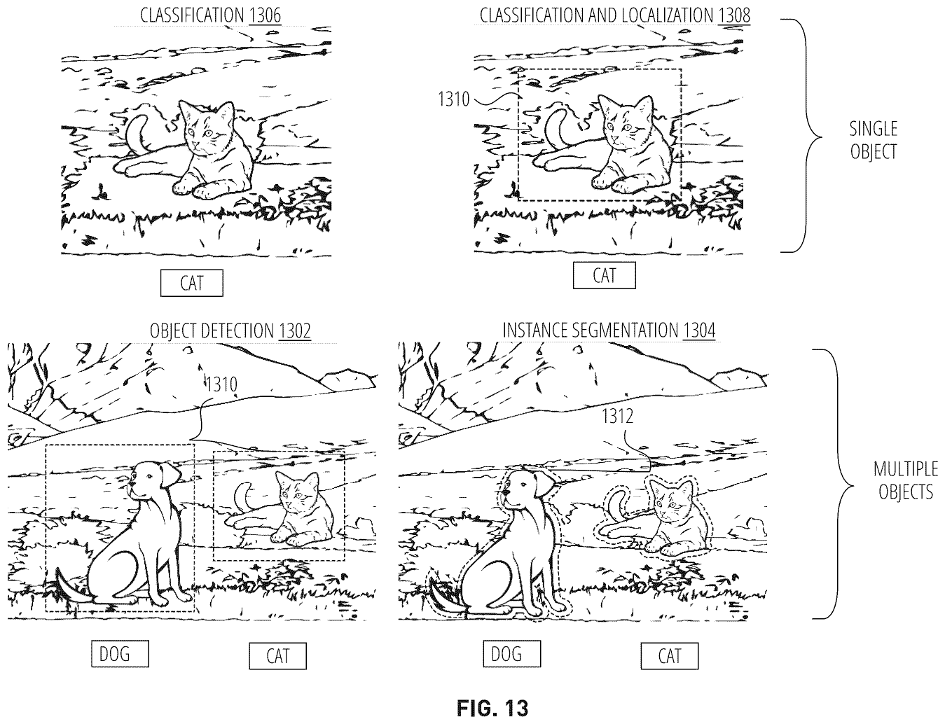

FIG. 13 illustrates a comparison between image classification, object detection, and instance segmentation. When a single object is in an image, the classification model 1306 maybe utilized to identify what is in the image. For instance, the classification model 1306 identifies that a cat is in the image. In addition to the classification model 1306, a classification and localization model 1308 may be utilized to classify and identify the location of the cat within the image with a bounding box 1310. When multiple objects are present within an image, an object detection model 1302 may be utilized. The object detection model 1302 utilizes bounding boxes to classify and locate the position of the different objects within the image. An instance segmentation model 1304 detects each object of an image, its localization and its precise segmentation by pixel with a segmentation region 1312.

The Image classification models classify images into a single category, usually corresponding to the most salient object. Photos and videos are usually complex and contain multiple objects. This being said, assigning a label with image classification models may become tricky and uncertain. Object detection models are therefore more appropriate to identify multiple relevant objects in a single image. The second significant advantage of object detection models versus image classification ones is that localization of the objects may be provided.

Some of the model that may be utilized to perform image classification, object detection, and instance segmentation include but are not limited to, Region-based Convolutional Network (R-CNN), Fast Region-based Convolutional Network (Fast R-CNN), Faster Region-based Convolutional Network (Faster R-CNN), Region-based Fully Convolutional Network (R-FCN), You Only Look Once (YOLO), Single-Shot Detector (SSD), Neural Architecture Search Net (NASNet), and Mask Region-based Convolutional Network (Mask R-CNN).

These models may utilize a variety of training datasets that include but are not limited to PASCAL Visual Object Classification (PASCAL VOC) and Common Objects in Context (COCO) datasets.

The PASCAL Visual Object Classification (PASCAL VOC) dataset is a well-known dataset for object detection, classification, segmentation of objects and so on. There are around 10 000 images for training and validation containing bounding boxes with objects. Although, the PASCAL VOC dataset contains only 20 categories, it is still considered as a reference dataset in the object detection problem.

ImageNet has released an object detection dataset since 2013 with bounding boxes. The training dataset is composed of around 500 000 images only for training and 200 categories.

The Common Objects in Context (COCO) datasets were developed by Microsoft. This dataset is used for caption generation, object detection, key point detection and object segmentation. The COCO object detection consists in localizing the objects in an image with bounding boxes and categorizing each one of them between 80 categories.

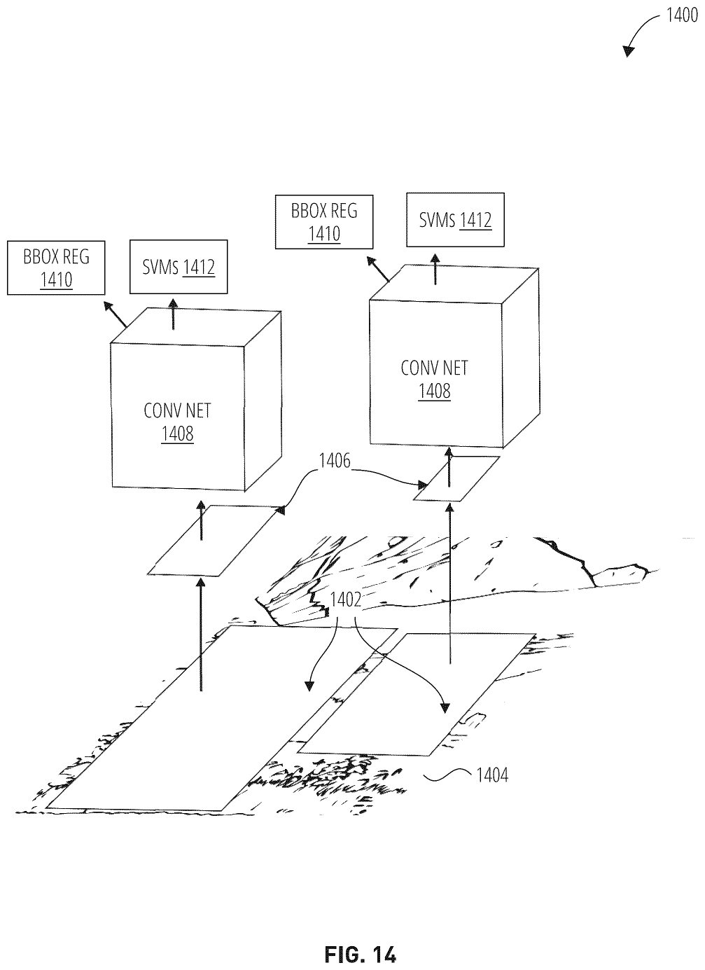

FIG. 14 illustrates an example of a Region-based Convolution Network 1400 (R-CNN). Each region proposal feeds a convolutional neural network (CNN) to extract a features vector, possible objects are detected using multiple SVM classifiers and a linear regressor modifies the coordinates of the bounding box. The regions of interest (ROI 1402) of the input image 1404. Each ROI 1402 of resized/warped creating the warped image region 1406 which are forwarded to the convolutional neural network 1408 where they are feed to the support vector machines 1412 and bounding box linear regressors 1410.

In R-CNN, the selective search method is an alternative to exhaustive search in an image to capture object location. It initializes small regions in an image and merges them with a hierarchical grouping. Thus the final group is a box containing the entire image. The detected regions are merged according to a variety of color spaces and similarity metrics. The output is a few number of region proposals which could contain an object by merging small regions.

The R-CNN model combines the selective search method to detect region proposals and deep learning to find out the object in these regions. Each region proposal is resized to match the input of a CNN from which the method extracts a 4096-dimension vector of features. The features vector is fed into multiple classifiers to produce probabilities to belong to each class. Each one of these classes has a support vector machines 1412 (SVM) classifier trained to infer a probability to detect this object for a given vector of features. This vector also feeds a linear regressor to adapt the shapes of the bounding box for a region proposal and thus reduce localization errors.

The CNN model described is trained on the ImageNet dataset. It is fine-tuned using the region proposals corresponding to an IoU greater than 0.5 with the ground-truth boxes. Two versions are produced, one version is using the PASCAL VOC dataset and the other the ImageNet dataset with bounding boxes. The SVM classifiers are also trained for each class of each dataset.

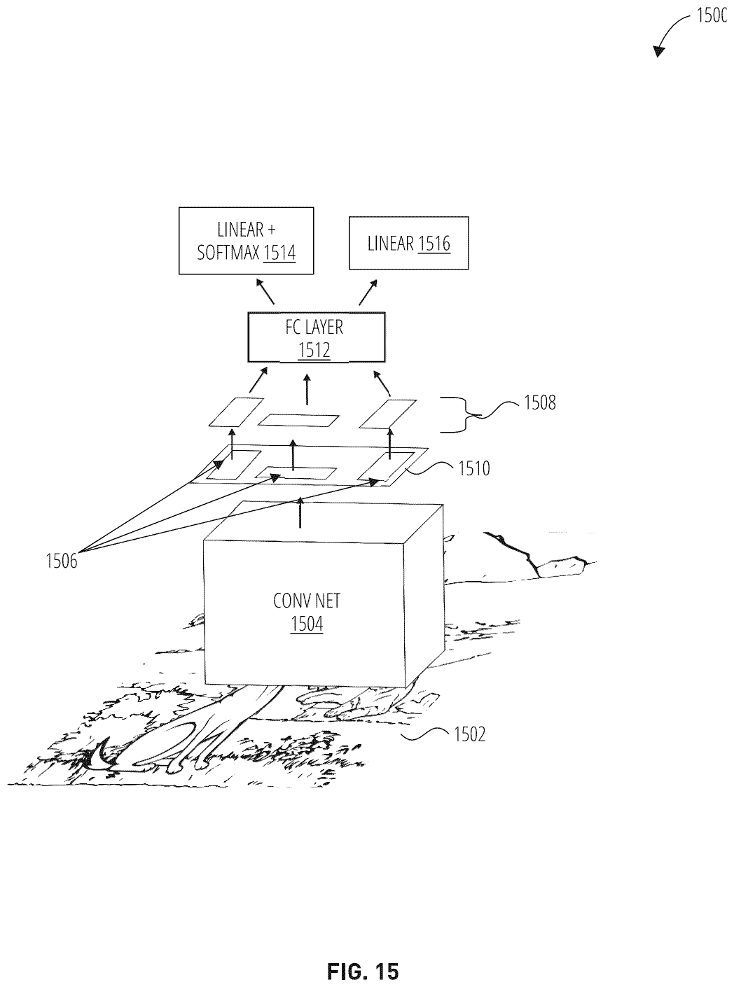

FIG. 15 illustrates an example of a Fast Region-based Convolutional Network 1500 (Fast R-CNN). The entire image (input image 1502) feeds a CNN model (convolutional neural network 1504) to detect RoI (ROI 1506) on the feature maps 1510. Each region is separated using a RoI pooling layer (ROI pooling layer 1508) and it feeds fully connected layers 1512. This vector is used by a softmax classifier 1514 to detect the object and by a bounding box linear regressors 1516 to modify the coordinates of the bounding box. The purpose of the Fast R-CNN is to reduce the time consumption related to the high number of models necessary to analyse all region proposals.

A main CNN with multiple convolutional layers is taking the entire image as input instead of using a CNN for each region proposals (R-CNN). Region of Interests (RoIs) are detected with the selective search method applied on the produced feature maps. Formally, the feature maps size is reduced using a RoI pooling layer to get valid Region of Interests with fixed height and width as hyperparameters. Each RoI layer feeds fully-connected layers creating a features vector. The vector is used to predict the observed object with a softmax classifier and to adapt bounding box localizations with a linear regressor.

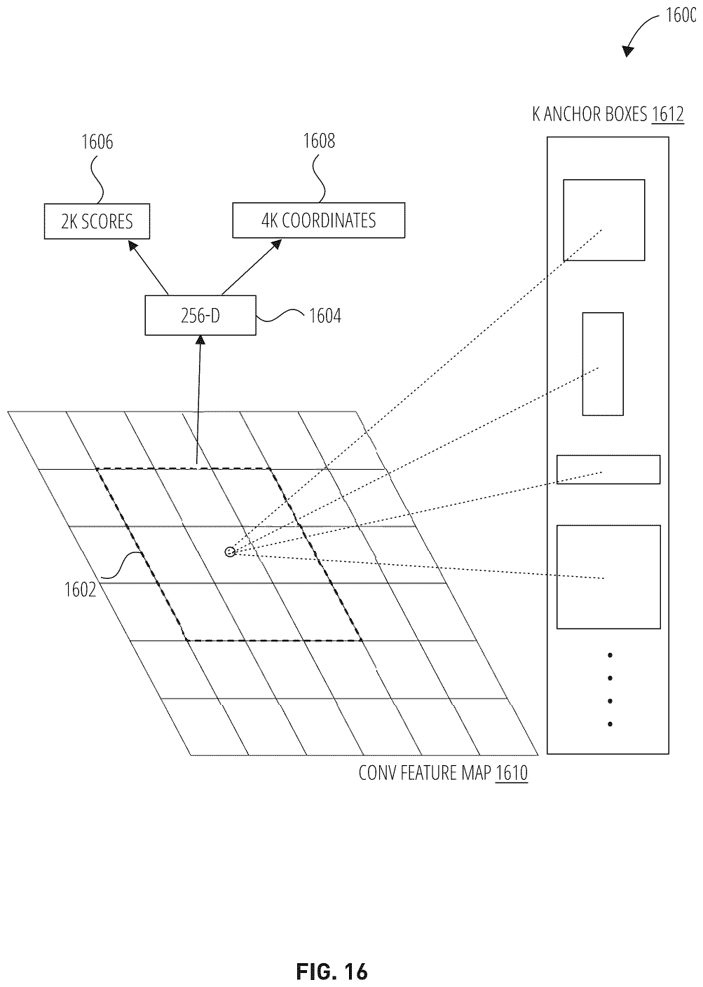

FIG. 16 illustrates an example of a Faster Region-based Convolutional Network 1600 (Faster R-CNN).

Region proposals detected with the selective search method were still necessary in the previous model, which is computationally expensive. Region Proposal Network (RPN) was introduced to directly generate region proposals, predict bounding boxes and detect objects. The Faster R-CNN is a combination between the RPN and the Fast R-CNN model.

A CNN model takes as input the entire image and produces feature map 1610. A window of size 3×3 (sliding window 1602) slides all the feature maps and outputs a features vector (intermediate layer 1604) linked to two fully-connected layers, one for box-regression and one for box-classification. Multiple region proposals are predicted by the fully-connected layers. A maximum of k regions is fixed thus the output of the box regression layer 1608 has a size of 4 k (coordinates of the boxes, their height and width) and the output of the box classification layer 1606 a size of 2 k (“objectness” scores to detect an object or not in the box). The k region proposals detected by the sliding window are called anchors.

When the anchor boxes 1612 are detected, they are selected by applying a threshold over the “objectness” score to keep only the relevant boxes. These anchor boxes and the feature maps computed by the initial CNN model feeds a Fast R-CNN model.

The entire image feeds a CNN model to produce anchor boxes as region proposals with a confidence to contain an object. A Fast R-CNN is used taking as inputs the feature maps and the region proposals. For each box, it produces probabilities to detect each object and correction over the location of the box.

Faster R-CNN uses RPN to avoid the selective search method, it accelerates the training and testing processes, and improve the performances. The RPN uses a pre-trained model over the ImageNet dataset for classification and it is fine-tuned on the PASCAL VOC dataset. Then the generated region proposals with anchor boxes are used to train the Fast R-CNN. This process is iterative.

FIG. 17 illustrates the comparison of segmentation accuracy (mIoU) and inference speed (FPS) on the Cityscapes test set. The black dots represent proposed PP-LiteSeg. The testing device is NVIDIA GTX 1080Ti. The experimental results demonstrate that PPLiteSeg achieves state-of-the-art trade-off between accuracy and speed.

FIG. 18 illustrates the architecture overview of PP-LiteSeg. PP-Liteseg consists of includes three modules: encoder, aggregation and decoder. A lightweight network is used as encoder to extract the features from different levels. The Simple Pyramid Pooling Module (SPPM) is responsible for aggregating the global context. The Flexible and Lightweight Decoder (FLD) fuses the detail and semantic features from high level to low level and outputs the result. Remarkably, FLD uses the Unified Attention Fusion Module (UAFM) to strengthen feature representations.

FIG. 19 illustrates (a) The conventional encoder-decoder, in which the decoder keeps the features channels the same. (b) The encoder and proposed Flexible and Lightweight Decoder (FLD). FLD gradually reduces the channels for the features from high level to low level. Moreover, the volume of FLD is adjusted to conform to the encoder.

FIG. 20A-FIG. 20C illustrates The framework of Unified Attention Fusion Module (UAFM) as FIG. 20A, the Spatial Attention Module as FIG. 20B, and the Channel Attention Module as FIG. 20C. UAFM first uses spatial or channel attention modules to produce the weight α, and then fuses the input features with Mul and Add operation.

FIG. 21 illustrates a Simple Pyramid Pooling Module (SPPM). Conv denotes convolution, batch norm and relu operations. The bin sizes of global-average-pooling are 1×1, 2×2 and 4×4 respectively.

FIG. 22 illustrates the qualitative comparison on the Cityscapes validation set. (a)-(c) represent the predicted image of baseline, baseline+FLD, baseline+FLD+SPPM, baseline+FLD+UAFM and baseline+FLD+SPPM+UAFM respectively, (f) denotes the ground truth.

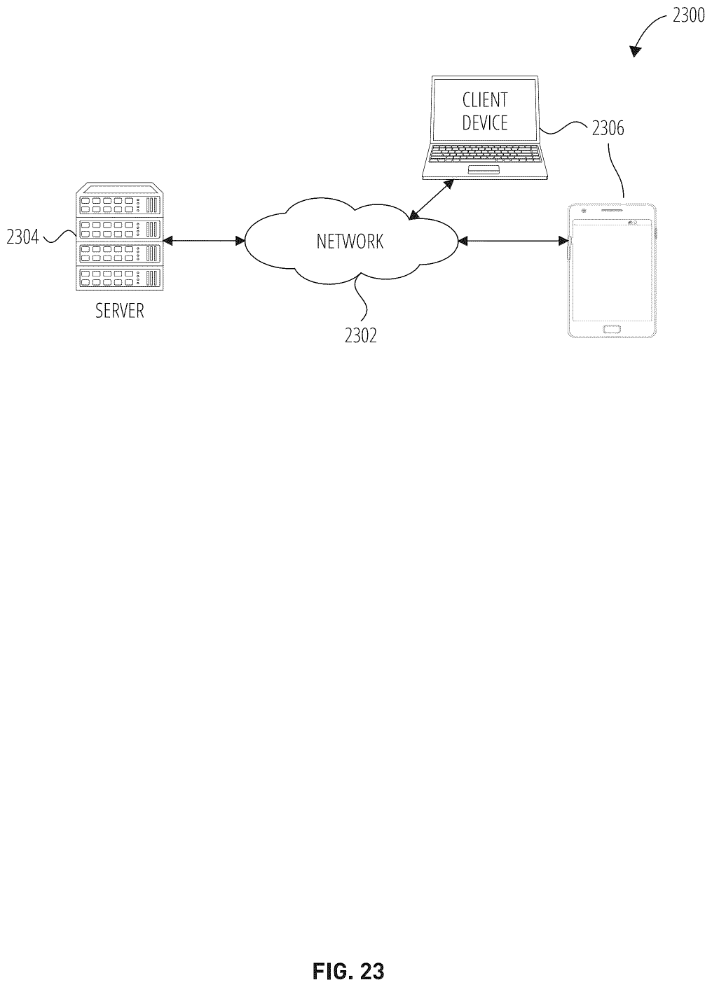

FIG. 23 illustrates a system 2300 in which a server 2304 and a client device 2306 are connected to a network 2302.

In various embodiments, the network 2302 may include the Internet, a local area network (“LAN”), a wide area network (“WAN”), and/or other data network. In addition to traditional data-networking protocols, in some embodiments, data may be communicated according to protocols and/or standards including near field communication (“NFC”), Bluetooth, power-line communication (“PLC”), and the like. In some embodiments, the network 2302 may also include a voice network that conveys not only voice communications, but also non-voice data such as Short Message Service (“SMS”) messages, as well as data communicated via various cellular data communication protocols, and the like.

In various embodiments, the client device 2306 may include desktop PCs, mobile phones, laptops, tablets, wearable computers, or other computing devices that are capable of connecting to the network 2302 and communicating with the server 2304, such as described herein.

In various embodiments, additional infrastructure (e.g., short message service centers, cell sites, routers, gateways, firewalls, and the like), as well as additional devices may be present. Further, in some embodiments, the functions described as being provided by some or all of the server 2304 and the client device 2306 may be implemented via various combinations of physical and/or logical devices. However, it is not necessary to show such infrastructure and implementation details in FIG. 23 in order to describe an illustrative embodiment.

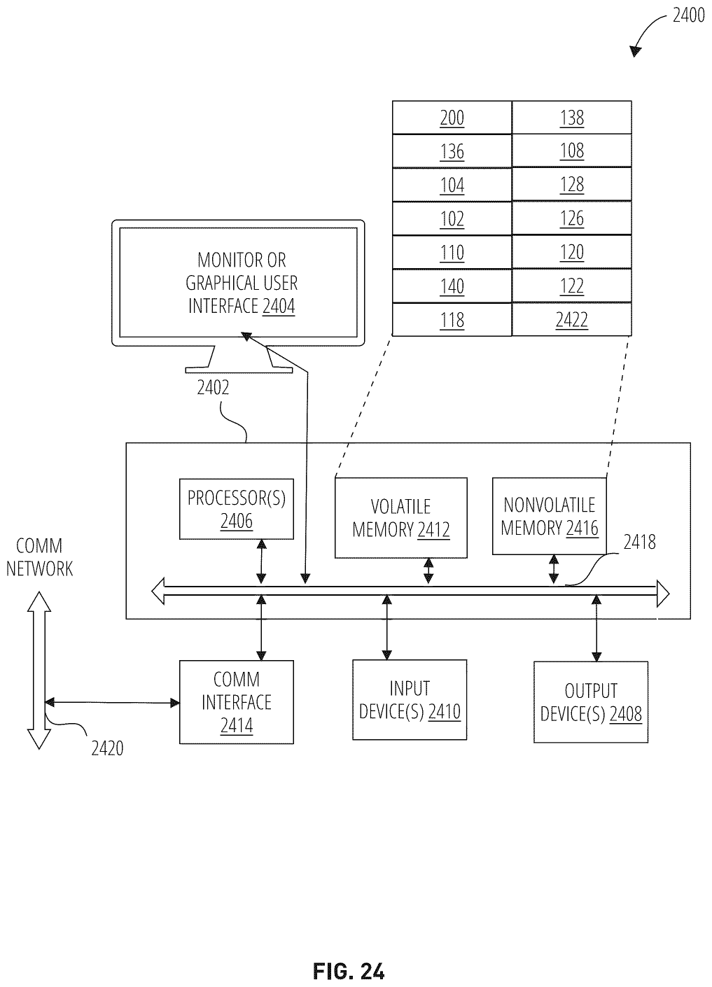

FIG. 24 is an example block diagram of a computing device 2400 that may incorporate embodiments of the present invention. FIG. 24 is merely illustrative of a machine system to carry out aspects of the technical processes described herein, and does not limit the scope of the claims. One of ordinary skill in the art would recognize other variations, modifications, and alternatives. In one embodiment, the computing device 2400 typically includes a monitor or graphical user interface 2404, a data processing system 2402, a communication network interface 2414, input device(s) 2410, output device(s) 2408, and the like.

As depicted in FIG. 24, the data processing system 2402 may include one or more processor(s) 2406 that communicate with a number of peripheral devices via a bus subsystem 2418. These peripheral devices may include input device(s) 2410, output device(s) 2408, communication network interface 2414, and a storage subsystem, such as a volatile memory 2412 and a nonvolatile memory 2416.

The volatile memory 2412 and/or the nonvolatile memory 2416 may store computer-executable instructions and thus forming logic 2422 that when applied to and executed by the processor(s) 2406 implement embodiments of the processes disclosed herein. In an embodiment, the volatile memory 2412 and the nonvolatile memory 2416 store instructions corresponding to the routine 200, a machine learning model 138, a machine learning pipeline 136, a navigation controller 108, a virtual environment generation system 104, a classification model 128, a robotic operating system 102, a scoring system 126, a training interface 110, a frame logger 120, a user interface dashboard 140, a training layer 122, and a virtual robot 118.

The input device(s) 2410 include devices and mechanisms for inputting information to the data processing system 2402. These may include a keyboard, a keypad, a touch screen incorporated into the monitor or graphical user interface 2404, audio input devices such as voice recognition systems, microphones, and other types of input devices. In various embodiments, the input device(s) 2410 may be embodied as a computer mouse, a trackball, a track pad, a joystick, wireless remote, drawing tablet, voice command system, eye tracking system, and the like. The input device(s) 2410 typically allow a user to select objects, icons, control areas, text and the like that appear on the monitor or graphical user interface 2404 via a command such as a click of a button or the like.

The output device(s) 2408 include devices and mechanisms for outputting information from the data processing system 2402. These may include the monitor or graphical user interface 2404, speakers, printers, infrared LEDs, and so on as well understood in the art.

The communication network interface 2414 provides an interface to communication networks (e.g., communication network 2420) and devices external to the data processing system 2402. The communication network interface 2414 may serve as an interface for receiving data from and transmitting data to other systems. Embodiments of the communication network interface 2414 may include an Ethernet interface, a modem (telephone, satellite, cable, ISDN), (asynchronous) digital subscriber line (DSL), FireWire, USB, a wireless communication interface such as BlueTooth or WiFi, a near field communication wireless interface, a cellular interface, and the like.

The communication network interface 2414 may be coupled to the communication network 2420 via an antenna, a cable, or the like. In some embodiments, the communication network interface 2414 may be physically integrated on a circuit board of the data processing system 2402, or in some cases may be implemented in software or firmware, such as “soft modems”, or the like.

The computing device 2400 may include logic that enables communications over a network using protocols such as HTTP, TCP/IP, RTP/RTSP, IPX, UDP and the like.

The volatile memory 2412 and the nonvolatile memory 2416 are examples of tangible media configured to store computer readable data and instructions to implement various embodiments of the processes described herein. Other types of tangible media include removable memory (e.g., pluggable USB memory devices, mobile device SIM cards), optical storage media such as CD-ROMS, DVDs, semiconductor memories such as flash memories, non-transitory read-only-memories (ROMS), battery-backed volatile memories, networked storage devices, and the like. The volatile memory 2412 and the nonvolatile memory 2416 may be configured to store the basic programming and data constructs that provide the functionality of the disclosed processes and other embodiments thereof that fall within the scope of the present invention.

Logic 2422 that implements embodiments of the present invention may be stored in the volatile memory 2412 and/or the nonvolatile memory 2416. Said logic 2422 may be read from the volatile memory 2412 and/or nonvolatile memory 2416 and executed by the processor(s) 2406. The volatile memory 2412 and the nonvolatile memory 2416 may also provide a repository for storing data used by the logic 2422.

The volatile memory 2412 and the nonvolatile memory 2416 may include a number of memories including a main random access memory (RAM) for storage of instructions and data during program execution and a read only memory (ROM) in which read-only non-transitory instructions are stored. The volatile memory 2412 and the nonvolatile memory 2416 may include a file storage subsystem providing persistent (non-volatile) storage for program and data files. The volatile memory 2412 and the nonvolatile memory 2416 may include removable storage systems, such as removable flash memory.

The bus subsystem 2418 provides a mechanism for enabling the various components and subsystems of data processing system 2402 communicate with each other as intended. Although the communication network interface 2414 is depicted schematically as a single bus, some embodiments of the bus subsystem 2418 may utilize multiple distinct busses.

It will be readily apparent to one of ordinary skill in the art that the computing device 2400 may be a device such as a smartphone, a desktop computer, a laptop computer, a rack-mounted computer system, a computer server, or a tablet computer device. As commonly known in the art, the computing device 2400 may be implemented as a collection of multiple networked computing devices. Further, the computing device 2400 will typically include operating system logic (not illustrated) the types and nature of which are well known in the art.

Terms used herein should be accorded their ordinary meaning in the relevant arts, or the meaning indicated by their use in context, but if an express definition is provided, that meaning controls.

“Circuitry” in this context refers to electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes or devices described herein, or a microprocessor configured by a computer program which at least partially carries out processes or devices described herein), circuitry forming a memory device (e.g., forms of random access memory), or circuitry forming a communications device (e.g., a modem, communications switch, or optical-electrical equipment).

“Firmware” in this context refers to software logic embodied as processor-executable instructions stored in read-only memories or media.

“Hardware” in this context refers to logic embodied as analog or digital circuitry.

“Logic” in this context refers to machine memory circuits, non transitory machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

“Software” in this context refers to logic implemented as processor-executable instructions in a machine memory (e.g. read/write volatile or nonvolatile memory or media).

Herein, references to “one embodiment” or “an embodiment” do not necessarily refer to the same embodiment, although they may. Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively, unless expressly limited to a single one or multiple ones. Additionally, the words “herein,” “above,” “below” and words of similar import, when used in this application, refer to this application as a whole and not to any particular portions of this application. When the claims use the word “or” in reference to a list of two or more items, that word covers all of the following interpretations of the word: any of the items in the list, all of the items in the list and any combination of the items in the list, unless expressly limited to one or the other. Any terms not expressly defined herein have their conventional meaning as commonly understood by those having skill in the relevant art(s).

Various logic functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on.

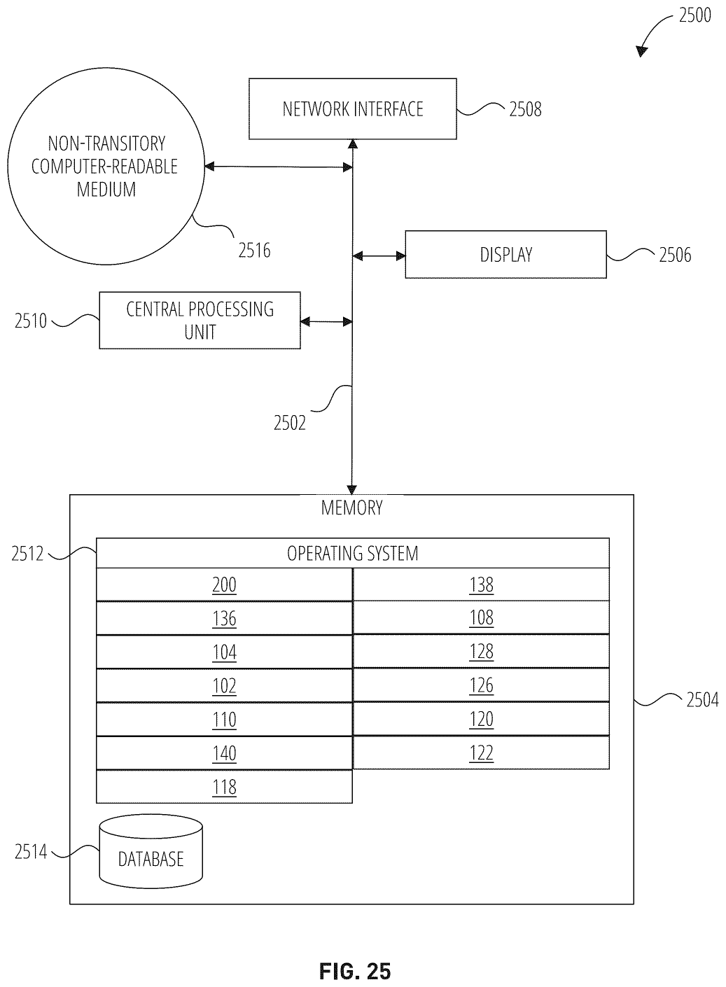

FIG. 25 illustrates several components of an exemplary system 2500 in accordance with one embodiment. In various embodiments, system 2500 may include a desktop PC, server, workstation, mobile phone, laptop, tablet, set-top box, appliance, or other computing device that is capable of performing operations such as those described herein. In some embodiments, system 2500 may include many more components than those shown in FIG. 25. However, it is not necessary that all of these generally conventional components be shown in order to disclose an illustrative embodiment. Collectively, the various tangible components or a subset of the tangible components may be referred to herein as “logic” configured or adapted in a particular way, for example as logic configured or adapted with particular software or firmware.

In various embodiments, system 2500 may comprise one or more physical and/or logical devices that collectively provide the functionalities described herein. In some embodiments, system 2500 may comprise one or more replicated and/or distributed physical or logical devices.

In some embodiments, system 2500 may comprise one or more computing resources provisioned from a “cloud computing” provider, for example, Amazon Elastic Compute Cloud (“Amazon EC2”), provided by Amazon.com, Inc. of Seattle, Washington; Sun Cloud Compute Utility, provided by Sun Microsystems, Inc. of Santa Clara, California; Windows Azure, provided by Microsoft Corporation of Redmond, Washington, and the like.

System 2500 includes a bus 2502 interconnecting several components including a network interface 2508, a display 2506, a central processing unit 2510, and a memory 2504.

Memory 2504 generally comprises a random access memory (“RAM”) and permanent non-transitory mass storage device, such as a hard disk drive or solid-state drive. Memory 2504 stores an operating system 2512.

These and other software components may be loaded into memory 2504 of system 2500 using a drive mechanism (not shown) associated with a non-transitory computer-readable 2516, such as a DVD/CD-ROM drive, memory card, network download, or the like. In an embodiment, the memory 2504 include instructions corresponding to routine 200, a machine learning model 138, a machine learning pipeline 136, a navigation controller 108, a virtual environment generation system 104, a classification model 128, a robotic operating system 102, a scoring system 126, a training interface 110, a frame logger 120, a user interface dashboard 140, a training layer 122, and a virtual robot 118.

Memory 2504 also includes database 2514. In some embodiments, system 2500 may communicate with database 2514 via network interface 2508, a storage area network (“SAN”), a high-speed serial bus, and/or via the other suitable communication technology.

In some embodiments, database 2514 may comprise one or more storage resources provisioned from a “cloud storage” provider, for example, Amazon Simple Storage Service (“Amazon S3”), provided by Amazon.com, Inc. of Seattle, Washington, Google Cloud Storage, provided by Google, Inc. of Mountain View, California, and the like.

Terms used herein should be accorded their ordinary meaning in the relevant arts, or the meaning indicated by their use in context, but if an express definition is provided, that meaning controls.

“Circuitry” in this context refers to electrical circuitry having at least one discrete electrical circuit, electrical circuitry having at least one integrated circuit, electrical circuitry having at least one application specific integrated circuit, circuitry forming a general purpose computing device configured by a computer program (e.g., a general purpose computer configured by a computer program which at least partially carries out processes or devices described herein, or a microprocessor configured by a computer program which at least partially carries out processes or devices described herein), circuitry forming a memory device (e.g., forms of random access memory), or circuitry forming a communications device (e.g., a modem, communications switch, or optical-electrical equipment).

“Firmware” in this context refers to software logic embodied as processor-executable instructions stored in read-only memories or media.

“Hardware” in this context refers to logic embodied as analog or digital circuitry.

“Logic” in this context refers to machine memory circuits, non transitory machine readable media, and/or circuitry which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

“Software” in this context refers to logic implemented as processor-executable instructions in a machine memory (e.g. read/write volatile or nonvolatile memory or media).

Herein, references to “one embodiment” or “an embodiment” do not necessarily refer to the same embodiment, although they may. Unless the context clearly requires otherwise, throughout the description and the claims, the words “comprise,” “comprising,” and the like are to be construed in an inclusive sense as opposed to an exclusive or exhaustive sense; that is to say, in the sense of “including, but not limited to.” Words using the singular or plural number also include the plural or singular number respectively, unless expressly limited to a single one or multiple ones. Additionally, the words “herein,” “above,” “below” and words of similar import, when used in this application, refer to this application as a whole and not to any particular portions of this application. When the claims use the word “or” in reference to a list of two or more items, that word covers all of the following interpretations of the word: any of the items in the list, all of the items in the list and any combination of the items in the list, unless expressly limited to one or the other. Any terms not expressly defined herein have their conventional meaning as commonly understood by those having skill in the relevant art(s).

Various logic functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on.

### Region-Based Fully Convolutional Network (R-FCN)

Fast and Faster R-CNN methodologies consist in detecting region proposals and recognize an object in each region. The Region-based Fully Convolutional Network (R-FCN) is a model with only convolutional layers allowing complete backpropagation for training and inference. The method merged the two basic steps in a single model to take into account simultaneously the object detection (location invariant) and its position (location variant).

A ResNet-101 model takes the initial image as input. The last layer outputs feature maps, each one is specialized in the detection of a category at some location. For example, one feature map is specialized in the detection of a cat, another one in a banana and so on. Such feature maps are called position-sensitive score maps because they take into account the spatial localization of a particular object. It consists of k*k*(C+1) score maps where k is the size of the score map, and C the number of classes. All these maps form the score bank. Basically, we create patches that can recognize part of an object. For example, for k=3, we can recognize 3×3 parts of an object.

In parallel, the method runs a RPN to generate Region of Interest (RoI). Finally, the method cuts each RoI in bins and checks them against the score bank. If enough of these parts are activated, then the patch vote ‘yes’, I recognized the object.

### You Only Look Once (YOLO)

The YOLO model directly predicts bounding boxes and class probabilities with a single network in a single evaluation. The simplicity of the YOLO model allows real-time predictions.

Initially, the model takes an image as input. It divides it into an S×S grid. Each cell of this grid predicts B bounding boxes with a confidence score. This confidence is simply the probability to detect the object multiply by the IoU between the predicted and the ground truth boxes.

The CNN used is inspired by the GoogLeNet model introducing the inception modules. The network has 24 convolutional layers followed by 2 fully-connected layers. Reduction layers with 1×1 filters⁴ followed by 3×3 convolutional layers replace the initial inception modules. The Fast YOLO model is a lighter version with only 9 convolutional layers and fewer number of filters. Most of the convolutional layers are pretrained using the ImageNet dataset with classification. Four convolutional layers followed by two fully-connected layers are added to the previous network and it is entirely retrained with the PASCAL VOC datasets.

The final layer outputs a S*S*(C+B*5) tensor corresponding to the predictions for each cell of the grid. C is the number of estimated probabilities for each class. B is the fixed number of anchor boxes per cell, each of these boxes being related to 4 coordinates (coordinates of the center of the box, width and height) and a confidence value.

With the previous models, the predicted bounding boxes often contained an object. The YOLO model however predicts a high number of bounding boxes. Thus there are a lot of bounding boxes without any object. The Non-Maximum Suppression (NMS) method is applied at the end of the network. It consists in merging highly-overlapping bounding boxes of a same object into a single one.

### Single-Shot Detector (SSD)

A Single-Shot Detector (SSD) model predicts all at once the bounding boxes and the class probabilities with an end-to-end CNN architecture.

The model takes an image as the input which passes through multiple convolutional layers with different sizes of filter (10×10, 5×5 and 3×3). Feature maps from convolutional layers at different position of the network are used to predict the bounding boxes. They are processed by a specific convolutional layers with 3×3 filters called extra feature layers to produce a set of bounding boxes similar to the anchor boxes of the Fast R-CNN.

Each box has 4 parameters: the coordinates of the center, the width and the height. At the same time, it produces a vector of probabilities corresponding to the confidence over each class of object.

The Non-Maximum Suppression method is also used at the end of the SSD model to keep the most relevant bounding boxes. The Hard Negative Mining (HNM) is then used because a lot of negative boxes are still predicted. It consists in selecting only a subpart of these boxes during the training. The boxes are ordered by confidence and the top is selected depending on the ratio between the negative and the positive which is at most 1/3.

### Neural Architecture Search Net (NASNet)

The Neural Architecture Search consists in learning the architecture of a model to optimize the number of layers while improving the accuracy over a given dataset.

The NASNet network has an architecture learned from the CIFAR-10 dataset and is trained with the ImageNet dataset. This model is used for feature maps generation and is stacked into the Faster R-CNN pipeline. Then the entire pipeline is retrained with the COCO dataset.

### Mask Region-Based Convolutional Network (Mask R-CNN)

Another extension of the Faster R-CNN model adds a parallel branch to the bounding box detection in order to predict object mask. The mask of an object is its segmentation by pixel in an image. This model outperforms the state-of-the-art in the four COCO challenges: the instance segmentation, the bounding box detection, the object detection and the key point detection.

The Mask Region-based Convolutional Network (Mask R-CNN) uses the Faster R-CNN pipeline with three output branches for each candidate object: a class label, a bounding box offset and the object mask. It uses Region Proposal Network (RPN) to generate bounding box proposals and produces the three outputs at the same time for each Region of Interest (RoI).

The initial RoIPool layer used in the Faster R-CNN is replaced by a RoIAlign layer. It removes the quantization of the coordinates of the original RoI and computes the exact values of the locations. The RoIAlign layer provides scale-equivariance and translation-equivariance with the region proposals.

The model takes an image as input and feeds a ResNeXt network with 101 layers. This model looks like a ResNet but each residual block is cut into lighter transformations which are aggregated to add sparsity in the block. The model detects RoIs which are processed using a RoIAlign layer. One branch of the network is linked to a fully-connected layer to compute the coordinates of the bounding boxes and the probabilities associated to the objects. The other branch is linked to two convolutional layers, the last one computes the mask of the detected object.

Three loss functions associated to each task to solve are summed. This sum is minimized and produces great performances because solving the segmentation task improve the localization and thus the classification.

What is claimed is:

1. A method comprises:
operating a virtual environment generation system configured to render a virtual environment comprising a course and obstacles;
configuring a robotic operating system comprising a navigation controller, a classification model, and sensor channels to operate as a virtual robot in the virtual environment;
operating a training interface configured to observe, configure, and record interactions between the virtual robot and the virtual environment, wherein the training interface comprises a user interface dashboard, a training layer, a frame logger, and a scoring system;
operating the training layer to adjust the complexity of the course and types and quantity of the obstacles presented to the virtual robot in the virtual environment configured by the testing configurations from the user interface dashboard;
operating the movement of the virtual robot in the virtual environment by way of a navigation controller to traverse through the course;
logging frames from the sensor channels of the virtual robot while navigating through the course and the obstacles through operation of the frame logger;
determining a navigation score for the virtual robot on interactions on the course through operation of the scoring system;
communicating logged frames to a machine learning pipeline and applying at least one filter to the logged frames to generate training frames for a machine learning model;
retraining the machine learning model with the training frames to generate a model update for the classification model;
applying the model update to the classification model and generating a new virtual robot version; and
ranking different virtual robot versions based on the navigation score.

2. The method of claim 1 wherein the sensor channels are image feeds of the virtual environment captured by virtualized cameras of the virtual robot.

3. The method of claim 2, wherein the frame logger captures an array of images from the sensor channels.

4. The method of claim 1 wherein the at least one filter is utilized to simulate variations in image quality, lens interferences, light intensity, light source location, surface texture, surface color, surface pattern, and surface reflectivity.

5. The method of claim 1, wherein the machine learning model is a convolutional neural network for object classification.

6. The method of claim 1, wherein the frame logger is controlled by inputs from the user interface dashboard.

7. The method of claim 1, wherein the navigation controller is configured by navigation instructions.

8. A computing apparatus comprising:
a processor; and
a memory storing instructions that, when executed by the processor, configure the apparatus to:
operate a virtual environment generation system configured to render a virtual environment comprising a course and obstacles;
configure a robotic operating system comprising a navigation controller, a classification model, and sensor channels to operate as a virtual robot version in the virtual environment;
operate a training interface configured to observe, configure, and record interactions between the virtual robot and the virtual environment, wherein the training interface comprises a user interface dashboard, a training layer, a frame logger, and a scoring system;
operate the training layer to adjust the complexity of the course and types and quantity of the obstacles presented to the virtual robot in the virtual environment configured by the testing configurations from the user interface dashboard;
operate the movement of the virtual robot in the virtual environment by way of a navigation controller to traverse through the course;
log frames from the sensor channels of the virtual robot while navigating through the course and the obstacles through operation of the frame logger;
determine a navigation score for the virtual robot on interactions on the course through operation of the scoring system;
communicate logged frames to a machine learning pipeline and applying at least one filter to the logged frames to generate training frames for a machine learning model;
retrain the machine learning model with the training frames to generate a model update for the classification model;
apply the model update to the classification model and generate a new virtual robot version; and
rank different virtual robot versions based on the navigation score.

9. The computing apparatus of claim 8, wherein the sensor channels are image feeds of the virtual environment captured by virtualized cameras of the virtual robot.

10. The computing apparatus of claim 9, wherein the frame logger captures an array of images from the sensor channels.

11. The computing apparatus of claim 8, wherein the at least one filter is utilized to simulate variations in image quality, lens interferences, light intensity, light source location, surface texture, surface color, surface pattern, and surface reflectivity.

12. The computing apparatus of claim 8, wherein the machine learning model is a convolutional neural network for object classification.

13. The computing apparatus of claim 8, wherein the frame logger is controlled by inputs from the user interface dashboard.

14. The computing apparatus of claim 8, wherein the navigation controller is configured by navigation instructions.

15. A non-transitory computer-readable storage medium, the computer-readable storage medium including instructions that when executed by a computer, cause the computer to:
operate a virtual environment generation system configured to render a virtual environment comprising a course and obstacles;
configure a robotic operating system comprising a navigation controller, a classification model, and sensor channels to operate as a virtual robot version in the virtual environment;
operate a training interface configured to observe, configure, and record interactions between the virtual robot and the virtual environment, wherein the training interface comprises a user interface dashboard, a training layer, a frame logger, and a scoring system;
operate the training layer to adjust the complexity of the course and types and quantity of the obstacles presented to the virtual robot in the virtual environment configured by the testing configurations from the user interface dashboard;
operate the movement of the virtual robot in the virtual environment by way of a navigation controller to traverse through the course;
log frames from the sensor channels of the virtual robot while navigating through the course and the obstacles through operation of the frame logger;
determine a navigation score for the virtual robot on interactions on the course through operation of the scoring system;
communicate logged frames to a machine learning pipeline and applying at least one filter to the logged frames to generate training frames for a machine learning model;
retrain the machine learning model with the training frames to generate a model update for the classification model;
apply the model update to the classification model and generate a new virtual robot version; and
rank different virtual robot versions based on the navigation score.

16. The computer-readable storage medium of claim 15, wherein the sensor channels are image feeds of the virtual environment captured by virtualized cameras of the virtual robot.

17. The computer-readable storage medium of claim 16, wherein the frame logger captures an array of images from the sensor channels.

18. The computer-readable storage medium of claim 15, wherein the at least one filter is utilized to simulate variations in image quality, lens interferences, light intensity, light source location, surface texture, surface color, surface pattern, and surface reflectivity.

19. The computer-readable storage medium of claim 15, wherein the machine learning model is a convolutional neural network for object classification.

20. The computer-readable storage medium of claim 15, wherein the frame logger is controlled by inputs from the user interface dashboard.
